(19) United States
(12) Patent Application Publication
(10) Pub. No.: US 2026/0342354 A1
(43) Pub. Date: Oct. 29, 2026

(54) REDUCING HARMONIC DISTORTION IN HIGH-SPEED PRECISION DIGITAL-TO-ANALOG CONVERTERS

(71) Applicant: Texas Instruments Incorporated, Dallas, TX (US)

(72) Inventors: Abhishek Ghosh, Bangalore (IN); Tanmay Neema, Bangalore (IN); Rahul Kumar, Jehanabad (IN); Vishal Monteiro, Bangalore (IN); Shubham Singh, New Delhi (IN)

(21) Appl. No.: 19/403,376

(22) Filed: Nov. 28, 2025

(30) Foreign Application Priority Data
Apr. 25, 2025 (IN) 202541039833

(51) Int. Cl. H03M 1/68

(52) U.S. Cl. CPC H03M 1/687

(57) ABSTRACT

A segmented digital-to-analog converter (DAC), including a thermometric segment, a binary segment, and an R-2R segment. The thermometric segment is arranged as slices, each with multiple resistive elements. The binary segment includes slices in a pseudo-differential architecture, each slice including multiple resistive elements. Switch logic controls the switching of the resistive elements in the thermometric and binary segments to maintain a constant transition vector value independent of the digital input code values. The R-2R segment includes a number of slices extending beyond the input code bit width. A pipelined multitone signal generator controls switches in the R-2R segment to correct for harmonic distortion.

### CROSS-REFERENCE TO RELATED APPLICATIONS

This application claims the benefit of Indian Patent Application No. IN 202541039833, filed on Apr. 25, 2025, which application is hereby incorporated herein by reference.

This application is related to co-pending U.S. Patent Application No. ______, filed on the same day as this application, entitled “REDUCING HARMONIC DISTORTION IN HIGH-SPEED PRECISION DIGITAL-TO-ANALOG CONVERTERS,” and associated with Attorney Docket No. T107218, which application is hereby incorporated herein by reference.

### BACKGROUND

The present disclosure relates generally to electronic systems and methods, and in particular embodiments, to reducing harmonic distortion in high-speed precision digital-to-analog converters (DACs).

Many system applications of modern electronic circuits require the conversion of digital data into analog signals. Circuits referred to as digital-to-analog converters generally receive digital input words or codes, for example in a data stream, and generate a corresponding analog output signal reflecting the code values in the input data stream. The bit width of the input code, and thus the precision of the DAC output signal, may vary according to the system application.

Precision digital-to-analog converter (DAC) circuits are often used in such applications as instrumentation and control, signal generation or synthesis, biasing circuits, and calibration applications. The performance requirements required by some applications can be quite stringent. For example, precision DACs may be called on to convert up to 20-bit digital data to a high frequency (e.g. 100 kHz) analog signal. Harmonic distortion in the synthesized analog output signal is a significant concern, especially in test and measurement applications.

### SUMMARY

In accordance to an embodiment, a digital-to-analog converter circuit includes: a thermometric segment corresponding to a number T of input bits, and having first and second output terminals, including: a first plurality of resistors, numbering M, M being at least 2T, each coupled to a first reference voltage terminal, the first plurality of resistors having substantially equal resistances with one another; and a first plurality of switches, numbering at least 2T, each associated with and coupled on one side to a corresponding one of the first plurality of resistors, each of the first plurality of switches configured to couple its associated to the first output terminal or the second output terminal responsive to a control signal for that switch; and an output amplifier having an input coupled to the first output terminal.

In accordance to an embodiment, a digital-to-analog converter circuit includes: a binary segment having first and second output terminals, the binary segment including one or more slices, each slice corresponding to one of a number B of input bits of an input code, each slice including: a first plurality of resistors, each coupled to a first reference voltage terminal, the first plurality of resistors having substantially equal resistances with one another; a first plurality of switches, each associated with and coupled to a corresponding one of the first plurality of resistors, each of the first plurality of switches configured to select, responsive to a control signal for that switch, the first output terminal or the second output terminal for coupling to its associated resistor; a second plurality of resistors, each coupled to a second reference voltage terminal, the second plurality of resistors having substantially equal resistances with one another and with the first plurality of resistors associated with its bit position; and a second plurality of switches, each associated with and coupled on one side to a corresponding one of the second plurality of resistors, each of the second plurality of switches configured to couple its associated resistor to the first output terminal or the second output terminal, responsive to a control signal for that switch; an output amplifier having an input coupled to the first output terminal; and switch logic, having an input configured to receive B input bits of the input code, and configured to present control signals, to the first and second pluralities of switches of each slice of the binary segment, to couple a single one of the first plurality of resistors to the first output terminal and to couple the other ones of the first plurality of resistors and each of the second plurality of resistors to the second output terminal responsive to the input bit corresponding to the slice having a first logic state, and to couple a single one of the second plurality of resistors to the first output terminal and the other ones of the second plurality of resistors and each of the first plurality of resistors to the second output terminal, responsive to the input bit corresponding to the slice having a second logic state; where each resistor of the first and second pluralities of resistors of each slice has a resistance twice the resistance of resistors of a slice corresponding to a next most significant input bit of the input code.

In accordance to an embodiment, a digital-to-analog converter circuit includes: a thermometric segment having first and second output terminals, and including: a plurality of slices numbering T, where each slice includes a plurality of elements numbering M, each element coupled to a first reference voltage terminal and having substantially equal resistances with one another; an output amplifier having a first input coupled to the first output terminal; and switch logic coupled to the plurality of slices, and configured to: receive T input code bits representing a first digital value VT[n]; responsive to the first digital value VT[n], present control signals to the plurality of slices to couple M×VT[n] elements between the first reference voltage terminal and the first output terminal; receive T input code bits representing a second digital value VT[n+1]; and responsive to the second digital value VT[n+1], change a selected number C of the control signals to couple M×VT[n+1] elements between the first reference voltage terminal and the first output terminal, the number C being a constant regardless of whether the second digital value VT[n+1] is greater than, less than, or the same as the first digital value VT[n].

In accordance to an embodiment, a digital-to-analog converter system includes: a digital-to-analog converter (DAC) having a digital input, having an analog output, and including a number N+E of slices arranged in one or more segments; and a signal generator circuit having an output coupled to the digital input of the DAC, the signal generator circuit configured to generate a digital multitone signal responsive to a first frequency tuning word (FTW) of N bits corresponding to a first tone and a second FTW of N bits corresponding to a second tone, by: at an output pipeline stage, presenting a first code value of the multitone signal to the DAC; and while, in a preceding pipeline stage, performing a calculation of a second code value of the multitone signal.

In accordance to an embodiment, a digital-to-analog converter circuit includes: a signal generator circuit including: a plurality of registers, each for storing an N-bit frequency tuning word (FTW) associated with a tone; a plurality of phase accumulators, each associated with one of the plurality of registers; a multiplexer having inputs coupled to outputs of the plurality of phase accumulators, and having a select input; a first mapping circuit having an input coupled to the output of the multiplexer, and configured to output a sine value; a summing circuit having an input coupled to the output of the first mapping circuit; a buffer having an input coupled to the output of the summing circuit; and pipeline control logic configured to control the multiplexer, the first mapping circuit, the summing circuit, and the buffer, in a pipelined manner; and a DAC array having an input coupled to the output of the buffer, and configured to output an analog signal responsive to a stream of input codes received at its input.

In accordance to an embodiment, a digital-to-analog converter system includes: a digital-to-analog converter (DAC) having a digital input, having an analog output, and including a number N+E of slices arranged in one or more segments; a signal generator circuit having an output coupled to the digital input of the DAC, the signal generator circuit configured to generate a digital multitone signal responsive to a first frequency tuning word (FTW) of N bits corresponding to a a fundamental frequency and a second FTW of N bits corresponding to a harmonic frequency of the fundamental frequency, by: at an output pipeline stage, presenting a first code value of the multitone signal to the DAC; and while, in a preceding pipeline stage, performing a calculation of a second code value of the multitone signal; and a harmonic distortion measurement circuit having an input coupled to the analog output of the DAC, configured to iteratively compute the second FTW having an amplitude and phase responsive to output analog signals from the DAC.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an electrical diagram, in block form, of an electronic system incorporating a digital-to-analog converter (DAC) integrated circuit according to the some embodiments of the present disclosure;

FIGS. 2A and 2B are electrical diagrams, in block form, of DAC circuits according to the prior art;

FIG. 3 is an electrical diagram, in block form, of a segmented DAC according to some embodiments of the present disclosure;

FIG. 4A is an electrical diagram, in schematic form, of a pseudo-differential thermometric segment according to some embodiments of the present disclosure;

FIG. 4B is an electrical diagram, in schematic form, of a slice of a thermometric DAC segment according to the prior art;

FIG. 4C is an electrical diagram, in schematic form, of an element of a slice of a thermometric segment according to some embodiments of the present disclosure;

FIG. 4D is an electrical diagram, in schematic form, of a thermometric segment according to some embodiments of the present disclosure;

FIG. 5A is flow diagram illustrating the operation of switch logic for a thermometric segment of the DAC of FIG. 3, according to an embodiment of the present disclosure;

FIG. 5B is a table illustrating an example of the operation of switch logic according to the flow diagram of FIG. 5A, according to an embodiment of the present disclosure;

FIG. 5C is an electrical diagram, in schematic form, of switch logic operating according to the flow diagram of FIG. 5A, according to an embodiment of the present disclosure;

FIG. 6 is an electrical diagram, in schematic form, of a binary segment of the segmented DAC of FIG. 3, according to some embodiments of the present disclosure;

FIG. 7 is an electrical diagram, in schematic form, of a slice in the binary segment of FIG. 6, according to an embodiment of the present disclosure;

FIG. 8 is a state diagram illustrating the operation of an example of switch logic in connection with a binary segment slice of FIG. 7, according to an embodiment of the present disclosure;

FIGS. 9A and 9B are electrical diagrams, in block form, of multitone correction signal generation circuits according to the prior art;

FIG. 10 is an electrical diagram, in block form, of a DAC including a pipelined multitone signal generation circuit, according to some embodiments of the present disclosure;

FIG. 11 is an electrical diagram, in schematic form, of thermometric, binary, and R-2R slices in a DAC, according to some embodiments of the present disclosure;

FIG. 12A is a functional diagram of direct digital frequency synthesis as incorporated into a pipelined multitone signal generation circuit of some embodiments of the present disclosure;

FIG. 12B includes waveform plots illustrating an example of the generation of a multitone signal according to some embodiments of the present disclosure;

FIG. 13 is an electrical diagram, in block form, of a pipelined multitone signal generation circuit, according to some embodiments of the present disclosure;

FIG. 14 is a table illustrating an example of the operation of a pipelined multitone signal generation circuit, according to some embodiments of the present disclosure;

FIG. 15 is a flow diagram, in block form, illustrating the operation of a harmonic distortion measurement circuit in a DAC, according to some embodiments of the present disclosure; and

FIG. 16 is a set of plots illustrating an example of the operation of a harmonic distortion measurement circuit, according to some embodiments of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” of “an example” in this description indicate that a particular configuration, structure or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some embodiments relate to circuits and methods of converting digital data to an analog signal.

In some applications, mismatches among nominally identical circuit elements, such as those used to implement a multiple-bit resistive or capacitive DAC, cause nonlinear distortion in the analog output signal. In those and other applications, dynamic error from asymmetric on-and-off switching of DAC elements, virtual ground sampling, and the like also causes distortion in the analog output signal. Stringent distortion limits (e.g., <~130 dBc total harmonic distortion, or THD) are desired for some system applications of high-speed (e.g., up to 100 kHz) and high-precision (e.g., 18-bit digital input code) DAC circuits, for example in the context of instrumentation and control systems. Some of the embodiments described in this specification relate to reduction of dynamic error and mitigation of static mismatches in high-frequency, high-precision DAC integrated circuits.

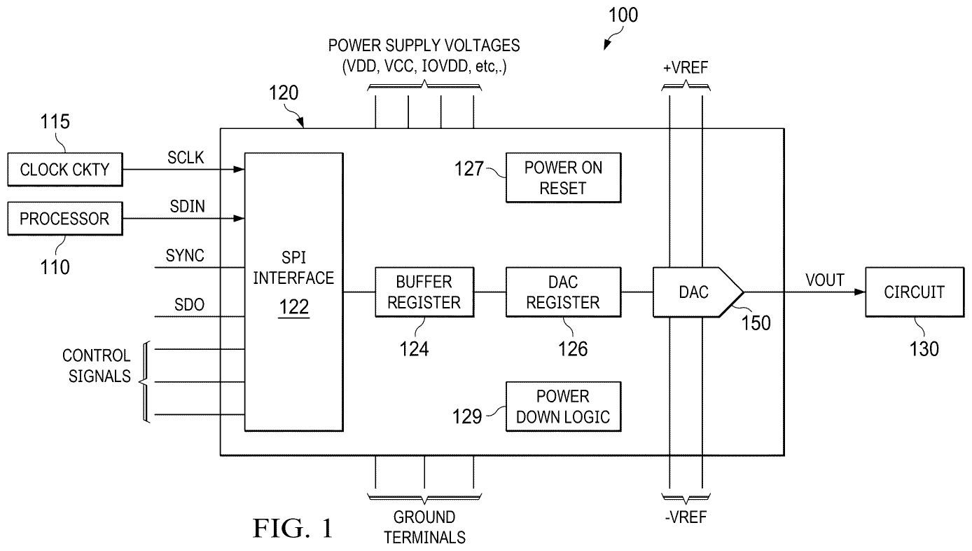

FIG. 1 illustrates system 100 incorporating a digital-to-analog converter (DAC) according to some embodiments. In this example, DAC integrated circuit 120 generates an analog output signal at its output terminal VOUT for application to an input of circuit 130, in response to a digital data stream SDIN generated by processor 110. The nature of circuit 130 depends on the particular system application. For example, in a high-precision control loop application, circuit 130 may represent one or more integrated circuits receiving an analog signal from DAC integrated circuit 120 for use as a control signal. In a test equipment application, circuit 130 represents a device under test (DUT), with DAC integrated circuit 120 generating an analog signal at terminal VOUT for use as a reference AC waveform for the particular test.

Processor 110 in system 100 of FIG. 1 corresponds to logic circuitry that generates a digital data stream corresponding to a sequence of DAC input code values defining the desired analog signal to be generated. In some embodiments, processor 110 may be implemented as a general-purpose or custom (e.g., application specific) microprocessor or microcontroller, coupled to or incorporating a memory, and configured to execute program instructions stored in such memory. In some embodiments, processor 110 may be implemented as a field programmable gate array (FPGA) or other semi-custom or custom logic circuitry. Other implementations are also possible.

In some embodiments, for example as shown in FIG. 1, DAC integrated circuit 120 includes input interface 122, coupled to processor 110 to receive the serial data stream at input terminal SDIN. In this example, input interface 122 is a serial-peripheral interface (SPI), and as such the digital data stream received at terminal SDIN is physically a serial data stream, synchronous with a serial clock signal SCLK generated by clock circuitry 115. In some embodiments, clock circuitry 115 may be a separate integrated circuit in system 100, or alternatively may be implemented within processor 110. In other embodiments, processor 100 may communicate DAC input codes as parallel digital data (e.g., of a bit width corresponding to the desired DAC precision), in which case input interface 122 of DAC integrated circuit 120 would be a parallel interface.

In some embodiments, DAC integrated circuit 120 has other timing and control terminals including SPI bus chip select input terminal SYNC, serial data output terminal SDO, and other terminals (not shown) for various control signals. DAC integrated circuit 120 in the example of FIG. 1 also has one or more power supply terminals, one or more ground terminals, and one or more reference voltage terminals as shown in FIG. 1.

In some embodiments, DAC integrated circuit 120 includes buffer register 124, which has an input coupled to SPI interface 122. Buffer register 124 buffers and stores the digital data received by input interface 122, for example to parallelize incoming serial input data into DAC input code words (e.g., 18-bit wide words). DAC register 126 is downstream from buffer register 124 in DAC integrated circuit 120, and stores one or more DAC input code words from buffer register 124 for presentation to DAC 150, allowing buffer register 124 to receive and parallelize serial input data received at input interface.

Other ancillary circuits and functions may also be provided in DAC integrated circuit 120 in some embodiments. In the example of FIG. 1, power on reset circuit 127 and power down logic 129 are provided in DAC integrated circuit 120. Other circuit functions, including clock circuits, voltage reference generators, control logic, and the like (not shown) may also be provided as suitable for the particular application.

According to some embodiments, DAC 150 is a segmented resistive DAC circuit that includes thermometric, binary, and R-2R segments. In some embodiments, DAC 150 is constructed as a pseudo-differential resistive DAC, such as described in copending U.S. application Ser. No. 18/814,694, filed Aug. 26, 2024, and entitled “A Multiplying Digital-to-Analog Converter,” commonly assigned herewith and incorporated herein by reference. According to those embodiments, DAC 150 receives both positive polarity and negative polarity reference voltages from terminals +VREF and −VREF as shown in FIG. 1. In other embodiments, DAC 150 is a resistive segmented DAC coupled to either positive or negative polarity reference voltages, from one of terminals +VREF and −VREF. In some embodiments, DAC 150 is a non-multiplying DAC, generating a time-varying analog signal from a stream of digital input codes of time-varying values, based on a substantially constant reference voltage. In other embodiments, DAC 150 is a multiplying DAC, generating a time-varying analog signal from a time-varying reference voltage, based on a scaling factor communicated as a digital input code. The construction and operation of DAC 150 according to some embodiments is described in detail below.

Ideally, the analog signal output by a DAC faithfully corresponds to the time-varying sequence of input codes applied to that DAC. In practice, however, distortion, in the form of non-linearities and harmonic distortion, is present to some extent in the output signals from the DAC. Causes of distortion include static mismatch among identical circuit elements (e.g., transistor variations), dynamic mismatch of corresponding electrical signals (e.g., rise and fall time differences of complementary signals), switching noise differences, quantization noise in the digital domain. The specifications of precision DAC integrated circuits typically specify a maximum limit on the total harmonic distortion (THD) in the output signal over the range of operating conditions.

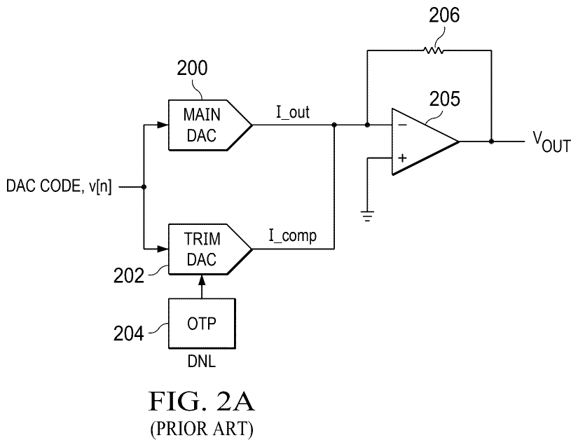

FIG. 2A illustrates a prior art DAC system in which non-linearity in the output of a “main” DAC 200 is trimmed at the time of manufacture using a “trim” DAC 202. In this prior art approach, non-linearities (e.g., integral non-linearity, or INL; differential non-linearity, or DNL) in the analog output signal of main DAC 200 are observed over the DAC input range. Parameters corresponding to the observed INL or DNL are programmed into one-time-programmable (OTP) memory 204. During normal operation, main DAC 200 and trim DAC 202 receive the same sequence of DAC input codes V[n], in response to which main DAC 200 and trim DAC 202 generate analog output currents I_out and I_trim, respectively, which are summed at the negative input of amplifier 205. Trim DAC 202 is controlled, according to the parameters stored in OTP memory 204, so that trim current I_trim compensates for (e.g., negates) distortion in the output current I_out from main DAC 200. In the arrangement of FIG. 2A, amplifier 206 is implemented (e.g., with feedback resistor 206 coupled between the amplifier output and its negative input, and with the positive input at ground) to produce a voltage V_out corresponding to output current I_out compensated by trim current I_trim.

FIG. 2B illustrates a prior art DAC system in which distortion caused by transition-induced switching errors in a DAC 210 is reduced by way of an output “deglitcher.” A segmented resistive DAC 210 includes, for example, a thermometric segment 214 and an R-2R segment 216. Switches 212 in segments 214 and 216 operate to selectively couple corresponding resistors to an input (negative input) of amplifier 220, for example according to a DAC input code. Noise generated by the switching of switches 212, in response to changing DAC input code values, can cause transition-induced errors at the output of amplifier 220, despite the effect of resistor 222 and capacitor 224 coupled between the input and output of amplifier 220. The deglitcher of this prior art system includes a clocked switch 226 coupled between the output of amplifier 220 and a ground-biased capacitor 228, which operate to periodically sample-and-hold the DAC output.

It has been observed, in connection with the embodiments described below, that the extent of improvements attained by the prior art approaches of FIGS. 2A and 2B do not achieve the extremely low distortion requirements of precision DACs in modern instrumentation, test, and control application. For example, the approach of FIG. 2A can leave some residual static mismatch, as well as uncorrected error due to variations in manufacturing process, power supply voltage, and temperature (PVT). Prior art dynamic calibration approaches such as dynamic element matching (DEM) and data-weighted averaging (DWA) can address those error causes, but often increase switching activity in the DAC, resulting in higher levels of switching noise beyond the capability of prior art deglitching as shown in FIG. 2B.

Some embodiments overcome some or all of the issues of the prior art.

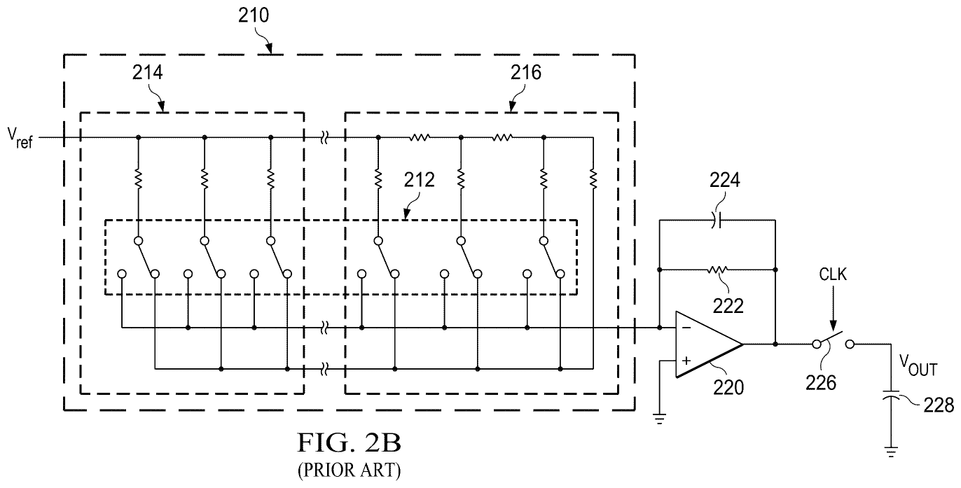

FIG. 3 illustrates DAC 150, according to various embodiments. DAC 150 of FIG. 3 may, in some embodiments, be incorporated into a DAC integrated circuit, for example DAC integrated circuit 120 in system 100 of FIG. 1. In these embodiments, DAC 150 has a segmented architecture, in that it includes multiple segments of different types that each contribute to the generation of an analog output signal Vₒᵤₜ (e.g., as a voltage) in response to a sample stream of N-bit DAC input codes V[n], synchronous with a sample clock signal (not shown in FIG. 3).

In the example of FIG. 3, DAC 150 includes thermometric segment 300, binary segment 302, and R-2R segment 304. Thermometric segment 300 is arranged into T “slices” 301₁ through 301_{T}, collectively corresponding to the T most significant bits (MSBs) of N-bit DAC input code V[n]. Binary segment 302 is arranged into B “slices” 303₁ through 301_{B}, each corresponding to one of the B upper least significant bits (ULSBs) of DAC input code V[n]. R-2R segment 304 is arranged into L+E “slices” 305₁ through 305_{L+E}. The L most significant slices of R-2R segment 304 each correspond to one of the L least significant bits (LSBs) of DAC input code V[n]. According to some embodiments, the E least significant slices of 304 are associated with additional LSBs beyond the N bits of the received DAC input code V[n] to attain additional reduction in output distortion, as described below.

In the embodiment of FIG. 3, DAC 150 is a resistive DAC implemented according to a pseudo-differential architecture, generally following the approach described in the above-incorporated U.S. application Ser. No. 18/814,694. Accordingly, each of segments 300, 302, 304 is biased from both a positive polarity reference voltage +V_{ref} and a negative polarity reference voltage −V_{ref}. Each slice 301, 303, 305 in each of segments 300, 302, 304 is coupled to output nodes OUT1 and OUT2.

The construction of each segment 300, 302, 304 is described in further detail below. In some embodiments, segments 300, 302, 304 are resistive DAC segments. In DAC 150, DAC input code V[n] is applied to digital processor 310, which in turn presents switch control signals SCW to switches in each of the slices 301, 303, 305 of segments 300, 302, 304, respectively. As shown in FIG. 3, digital processor 310 includes the circuits or functions of switch logic 312 and signal conditioning circuit 314. Examples of the construction and operation of these functions in digital processor 310 are described in detail below.

Output node OUT1 is coupled to a negative input of amplifier 320. Output node OUT2 is coupled to the output of ground buffer 330, which has a feedback input coupled to output node OUT2 and another input coupled to a common potential (e.g., circuit ground), at the positive input of amplifier 320. Alternatively, output node OUT2 from segments 300, 302, 304 may be coupled to the common potential directly, without ground buffer 330. Amplifier 320 in this embodiment is configured as a current-to-voltage buffer, with a feedback resistor 322 and feedback capacitor 324 coupled in parallel between the output and the negative input of amplifier 320.

In the operation of DAC 150 according to some embodiments, each of slices 301, 303, 305 switches resistances biased from reference voltages +V_{ref} and −V_{ref} to one of output nodes OUT1 and OUT2 in response to the switch control signals SCW, establishing currents at output nodes OUT1 and OUT2 corresponding to the value of DAC input code V[n]. Amplifier 320 presents a voltage Vₒᵤₜ in the form of an analog signal in response to the current at output node OUT1, reflecting the input signal represented by the sample stream of DAC input codes V[n].

In some embodiments, DAC 150 may alternatively be implemented according to architectures other than a pseudo-differential arrangement. For example, one or more of segments 300, 302, 304 may be biased from a single polarity reference voltage (e.g., voltage +V_{ref}), rather than from both positive and negative polarity reference voltages as in the pseudo-differential architecture of thermometric segment 300 of FIG. 3. Other arrangements of the DAC slices and segments, output amplifier, bias scheme, etc. are also contemplated.

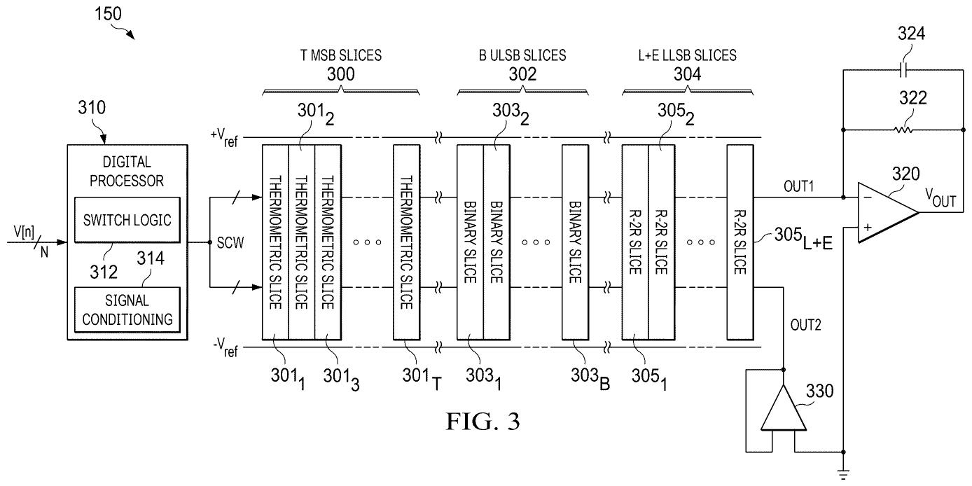

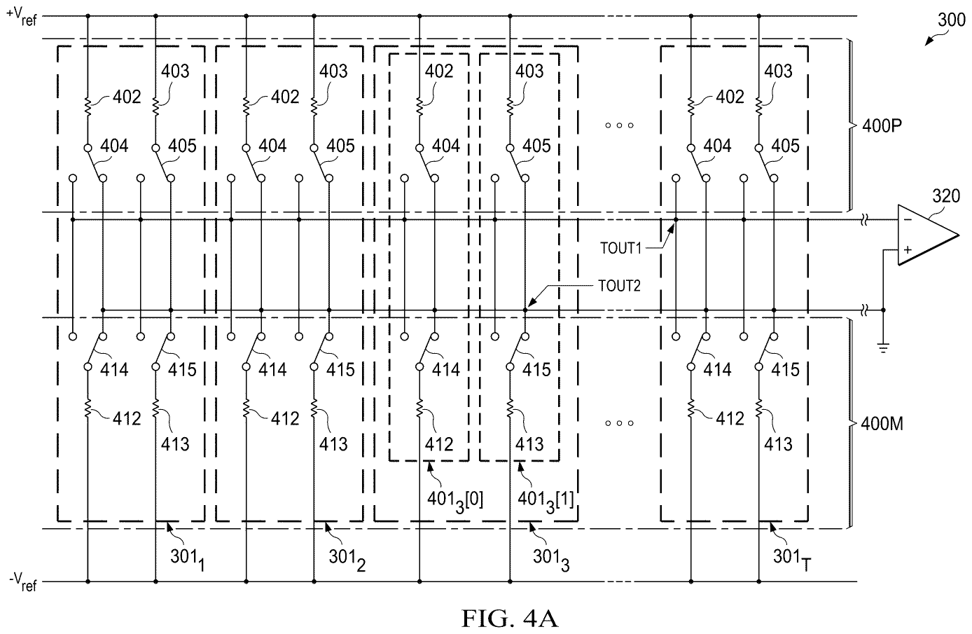

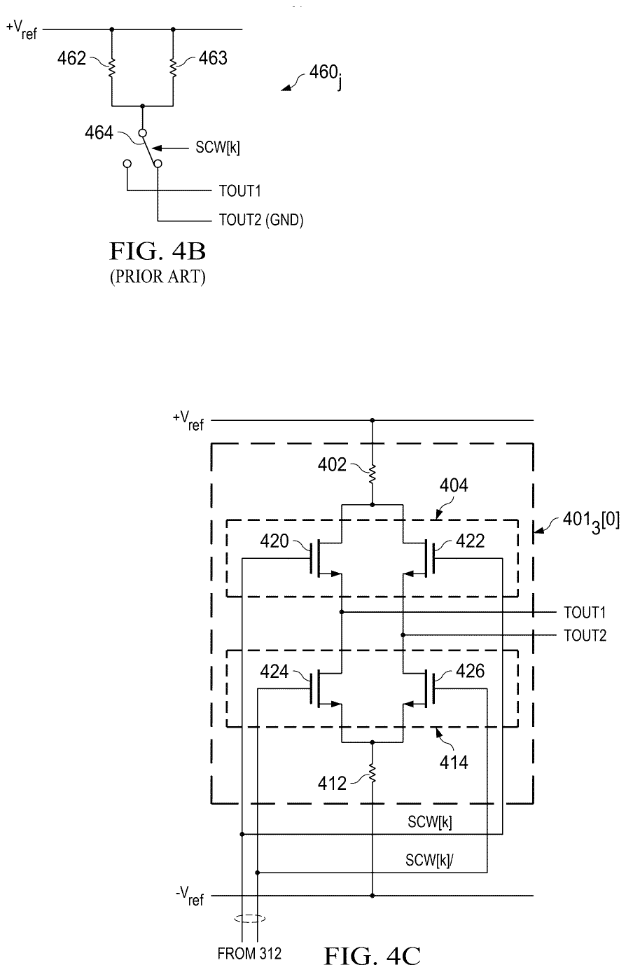

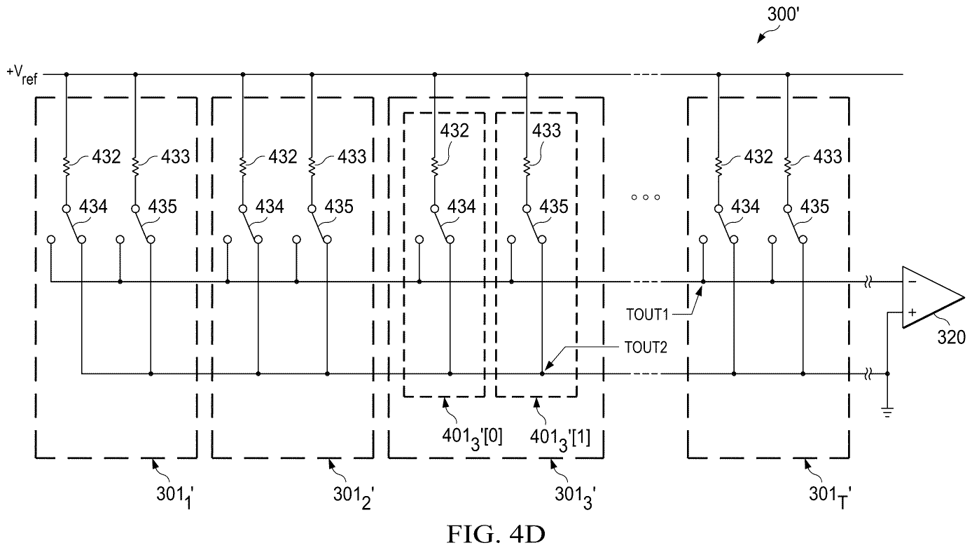

FIG. 4A illustrates the construction of thermometric segment 300, according to some embodiments. As mentioned above, thermometric segment 300 includes T slices 301₁ through 301_{T}, which collectively correspond to the T MSBs of N-bit DAC input code V[n]. However, individual ones of thermometric slices 301₁ through 301_{T} (collectively or generically referred as slices 301) are not associated with specific bits of DAC input code V[n] in these embodiments.

In the pseudo-differential architecture of DAC 150 according to some embodiments, thermometric segment 300 includes portion 400P biased from positive polarity reference voltage +V_{ref} and portion 400M biased from negative polarity reference voltage −V_{ref}. Each slice 301 in this embodiment is biased from both reference voltages +V_{ref} and −V_{ref}, and as such includes components in each of portions 400P, 400M.

According to these embodiments, slices 301 of thermometric segment 300 are “sub-segmented”, in that each slice 301 includes multiple resistive elements in parallel to establish an overall resistance R for that slice. In this embodiment, each slice 301 includes, in portion 400P, two resistors 402 and 403 coupled on one side to reference voltage +V_{ref} and coupled on another side to switches 404 and 405, respectively. Each slice 301 also includes, in portion 400M, two resistors 412 and 413, each coupled on one side to reference voltage −V_{ref} and on another side to switches 414 and 415, respectively. As shown in FIG. 4A for representative slice 301₃, resistors 402, 412 and switches 404 and 414 constitute resistive element 401₃[0] in slice 301₃. and resistors 403, 413 and switches 405 and 415 constitute a second resistive element 401₃[1] in slice 301₃.

Switches 404, 405, 414, 415 each have terminals coupled to output nodes TOUT1 and TOUT2. In the segmented architecture of DAC 150 according to some embodiments (e.g., in FIG. 3), output nodes TOUT1, TOUT2 of thermometric segment 300 are coupled to output nodes OUT1, OUT2. Output node TOUT1 is coupled to the negative input of amplifier 320, and output node TOUT2 is coupled to the positive input of amplifier 320 at circuit ground (e.g., via ground buffer 330 as shown in FIG. 3). Each switch 404, 405, 414, 415 operates to couple its corresponding resistor 402, 403, 412, 413 to either output node TOUT1 or output node TOUT2, in response to switch control signals SCW from switch logic 312 (FIG. 3) according to the value of DAC input code V[n].

In some embodiments according to the pseudo-differential architecture of FIG. 3, switches 404 and 414 operate complementarily relative to one another, such that one of resistors 402 and 412 is coupled to output node TOUT1 and the other is coupled to output node TOUT2 for each sample of DAC input code V[n]. As such, output node TOUT1 receives either a positive current from reference voltage +V_{ref} through resistor 402 or a negative current from reference voltage −V_{ref} through resistor 412. Similarly, switches 405 and 415 in the same slice operate complementarily, coupling one of resistors 403 and 413 to output node TOUT1 and the other to output node TOUT2, establishing either a positive or negative current into the negative input of amplifier 320. The elements 401ₖ[0] and 401ₖ[1] within a given slice 301ₖ are controlled independently from one another. For example, referring to slice 301₃ shown in FIG. 4A, complementary switches 404 and 414 in element 401₃[0] are controlled separately and independently of complementary switches 405 and 415 in element 401₃[1].

In this embodiment in which slices 301 are sub-segmented into two resistive elements, each of resistors 402, 403, 412, and 413 has a resistance (2R) that is twice that of the overall resistance R of the slice. Alternatively, slices 301 may be sub-segmented into four resistive elements (each resistor having a resistance 4R), eight resistive elements (each resistor having a resistance 8R), etc.

FIG. 4B illustrates a slice (or portion of a slice) 460; according to a prior art implementation. Slice 460; includes two resistors 462, 463, each coupled on one side to reference voltage +V_{ref} and on another side to switch 464. This splitting of the resistance R of slice 460ⱼ into two resistors 462, 463, each of resistance 2R, is believed to provide improved static differential non-linearity (DNL) performance. In this prior art arrangement of FIG. 4B, switch 464 is controlled by a switch control signal SCW[k] to connect both resistors 462, 463 to output node TOUT1 (e.g., at an amplifier input), or to circuit ground at output node TOUT2.

In contrast, as described above, each resistor 402, 403, 412, 413 in each slice 301 of thermometric segment 300 according to some embodiments is individually associated with a corresponding switch 404, 405, 414, 415, respectively, as shown in FIG. 4A. FIG. 4C illustrates the construction of switches 404 and 414 in a representative resistive element 401₃[0] of slice 301₃ in thermometric segment 300 of FIG. 4A. In this example, switch 404 includes n-channel metal-oxide-semiconductor (NMOS) transistors 420 and 422 having drains coupled to resistor 402, which in turn is coupled to reference voltage +V_{ref}. The source of transistor 420 is coupled to output node TOUT1, and the source of transistor 422 is coupled to output node TOUT2. Switch 414 similarly includes NMOS transistors 424 and 426 having drains coupled to resistor 412, which in turn is coupled to reference voltage −V_{ref}. The source of transistor 424 is coupled to output node TOUT1, and the source of transistor 426 is coupled to output node TOUT2. One or more of transistors 420, 422, 424, 426 may alternatively be implemented as p-channel MOS transistors, bipolar junction transistors, or the like. Complementary switch control signals SCW[k] and SCW[k]/from switch logic 312 in digital processor 310 are communicated to switches 404, 414. The gates of NMOS transistors 420 and 426 receive signal SCW[k], and the gates of NMOS transistors 422 and 424 receive complementary signal SCW[k]/.

In operation, a high logic level at signal SCW[k] and thus a low logic level at signal SCW[k]/causes NMOS transistors 420 and 426 to turn on, and NMOS transistors 422 and 424 to turn off. In this condition, switch 404 operates to couple resistor 402 (and thus a positive current from reference voltage +V_{ref} to output node TOUT1 at the negative input of amplifier 320, while switch 414 operates to couple resistor 412 (and thus a negative current from reference voltage −V_{ref} to output node TOUT2 at circuit ground. The opposite logic levels of signals SCW[k] and SCW[k]/(low and high, respectively), causes switch 404 to couple the positive current through resistor 402 to output node TOUT2, and switch 414 to couple the negative current through resistor 412 to output node TOUT1.

According to some of these embodiments, the multiple elements within each slice 301 are independently controlled from one another. For example, switches 405 and 415 of element 401₃[1] of slice 301₃ of FIG. 4A are controlled by a separate switch control signal pair (e.g., SCW[k+1] and SCW[k+1]/), independently of switches 404 and 414 of element 401₃[0] in the same slice 301₃.

Referring back to FIG. 4A, thermometric segment 300 conducts a current to the negative input of amplifier 320 according to a thermometric code. In the example of FIG. 4A in which each of T slices 301 is sub-segmented by a factor of two, the thermometric code determining the output current includes 2T bits, each independently controlling one of two elements 401[0] and 401[1] of each slice 301. In the pseudo-differential architecture of thermometric segment 300, where the reference voltages +V_{ref} and −V_{ref} have the same amplitude (|V_{ref}|) and opposite polarity, the net current IOUT_{T} into amplifier 320 from thermometric segment 300 can be expressed as:

$${IOUT}_{T} = \frac{{V}_{ref} \cdot k}{2 R} - \frac{[ {V}_{ref} \cdot ( 2 T - k ) ]}{2 R} = \frac{[ ( 2 k - 2 T ) \cdot {V}_{ref} ]}{2 R} = \frac{[ ( k - T ) \cdot {V}_{ref} ]}{R} \qquad ( 1 )$$

where the resistance of each resistor 402, 403, 412, 413 is 2R, and where k is the number of switches 404, 405 coupling its respective resistor 402, 403 to output node TOUT1, based on the switch control signals SCW from switch logic and signal conditioning circuit 130. As the input signal changes from one DAC input code V[n] to the next V[n+1], the numbers of switches 404, 405, 414, 415 in slices 301 that couple their associated resistors 402, 403, 412, 413 to output nodes OUT1 and OUT2 change. In this description, the number of switches 404, 405, 414, 415 that change position from one DAC input code V[n] to the next V[n+1] is referred to the thermometric transition vector K[n].

FIG. 4D illustrates thermometric segment 300′ according to other embodiments. In this example, thermometric segment 300′ is biased from a single polarity reference voltage +V_{ref}, rather than both positive and negative polarity reference voltages as in the pseudo-differential architecture of thermometric segment 300 of FIG. 4A. As such, thermometric segment 300′ of FIG. 4D effectively corresponds to upper portion 400P of thermometric segment 300 as shown in FIG. 4A, without lower portion 400M.

Thermometric segment 300′ of FIG. 4D includes T slices 301₁′ through 301_{T}′. The T slices 301′ are not individually associated with particular bits of the T MSBs of DAC input code V[n]. Each of slices 301′ is sub-segmented to include, in this example, two resistors 432, 433 coupled between reference voltage +V_{ref} and a corresponding switch 434, 435, respectively. As illustrated in slice 301₃′ by way of example, the combination of resistor 432 and switch 434 in a given slice 301′ constitutes one resistive element 401₃′[0], and the combination of resistor 433 and switch 435 constitutes a second resistive element 401₃′[1]. Alternatively, each slice 301′ may be sub-segmented to include four, eight, or another number of resistive elements. In the example of FIG. 4C, the two resistors 432, 433 have the same resistance as each other, and as the two resistors 432, 433 in all of the other slices 301′ of thermometric segment 300′. Each switch 434, 435 of each segment 301′ responds to a corresponding switch control signal SCW (not shown) to selectively couple its respective resistor 432, 433 to either output node TOUT1 or output node TOUT2. As in thermometric segment 300 described above, output node TOUT1 is coupled to the negative input of amplifier 320, and output node TOUT2 is coupled to circuit ground (e.g., either directly or via a ground buffer 330) along with the positive input of amplifier 320.

In the operation of thermometric segment 300′ of FIG. 4D, switch logic and signal conditioning circuit 130 generates switch control signals SCW to cause switches 434, 435 to couple a selected number of resistive elements 401ₖ′ to output node TOUT1 to source a current into amplifier 320 at an amplitude corresponding to the T MSBs of DAC input code V[n] (e.g., according to a thermometer code). As in thermometric segment 300 of FIG. 4A, the number of switches 434, 435 in slices 301′ that couple their associated resistors 432, 433 to output node TOUT1 will change with changes in successive DAC input codes V[n]. The number of switches 434, 435 that change position as the input sample values change from one DAC input code V[n] to the next DAC input code V[n+1] is the thermometric transition vector K[n].

According to some embodiments, the sub-segmenting of thermometric slices that is enabled by the provision of an independent switch for each resistor, within each of two or more resistive elements for each slice, enables the value of the thermometric transition vector K[n] to be independent of the input signal, and to remain constant from one DAC input code value to the next regardless of the DAC input code values. This separation of the thermometric transition vector K[n] from the input signal can reduce spurious harmonics in the output signal, which are a major contributor to THD. Maintaining a constant value of thermometric transition vector K[n] also has the effect of moving intersymbol interference (ISI) errors to DC (f=0). According to some embodiments, sub-segmenting of the thermometric slices further enables the rotation of the “on” switches through the sub-segments, reducing residual static mismatch errors.

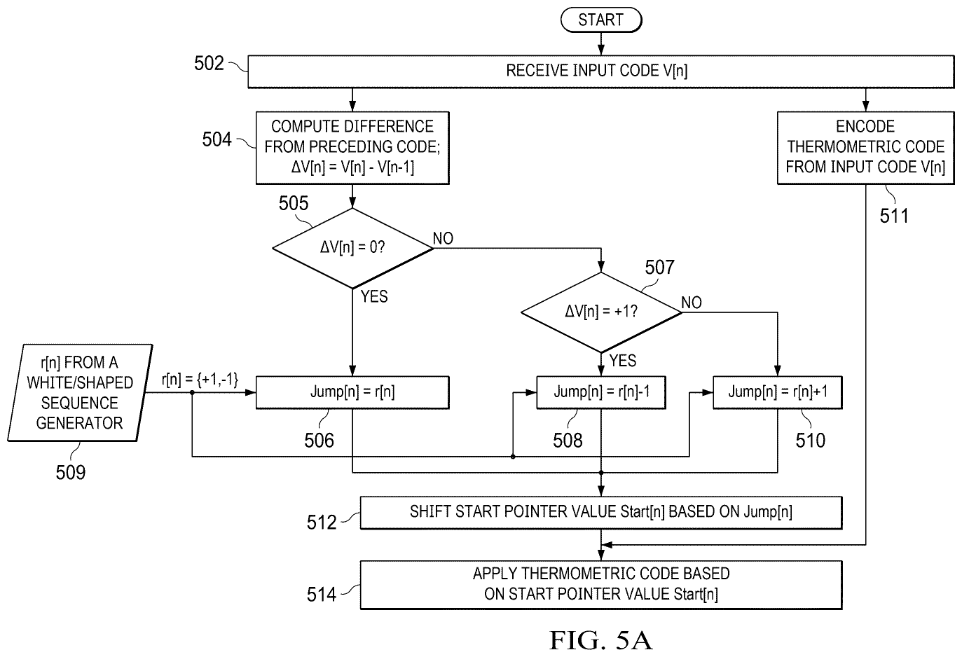

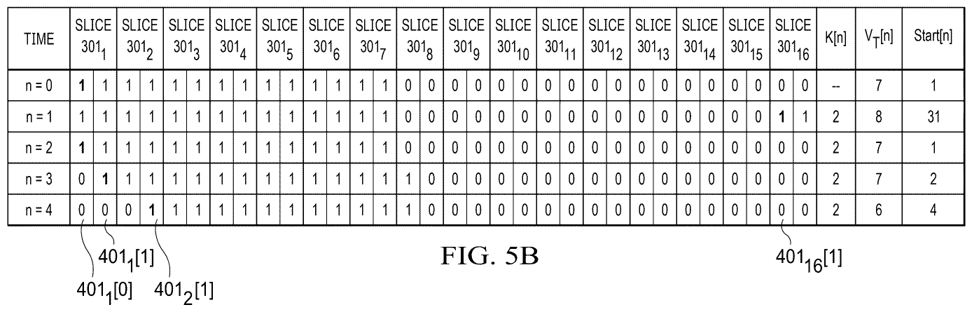

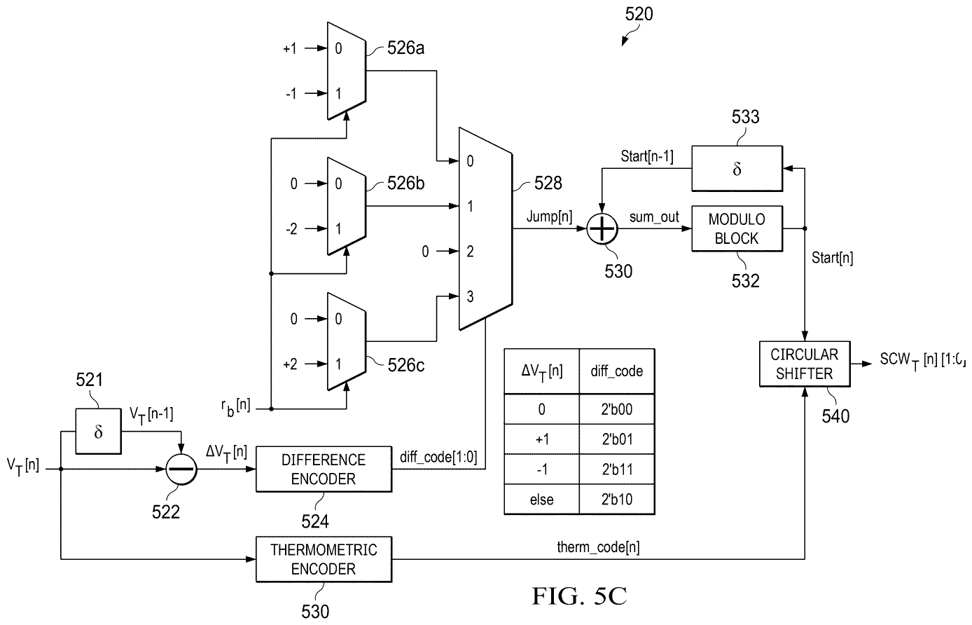

FIGS. 5A through 5C illustrate the implementation of switch logic 312 and its operation in controlling thermometric segment 300 of DAC 150 to maintain a constant transition vector K[n] value over a sequence of DAC input codes V[n], according to some embodiments. In addition, the example of FIGS. 5A through 5C further enables rotation of the currents over the slices 301 of thermometric segment 300. The implementation and operation of switch logic 312 shown by example in FIGS. 5A through 5C may be applied to thermometric segments of various architectures, including the pseudo-differential architecture such as shown in FIG. 4A, and the single polarity reference voltage architecture such as shown in FIG. 4D.

FIG. 5A is a flow diagram of the operation of switch logic 312 in connection with these embodiments. FIG. 5B is a table indicating the state of switches 404, 405 in the two resistive elements 401ₖ[0] and 401ₖ[1] for each of sixteen slices 301₁ through 301₁₆ of thermometric segment 300, associated with T=16 MSBs of N-bit DAC input code V[n]. FIG. 5C illustrates an example architecture of switch logic 312 for performing the operations of the flow diagram of FIG. 5A.

The algorithm of FIG. 5A may be understood with reference to an example, as shown in FIG. 5B. Each element 401ₖ[0], 401ₖ[1] having a “1” entry in FIG. 5B indicates that its corresponding switch 404 or 405, as the case may be, is controlled by switch logic 312 to couple its associated resistor 402 or 403, respectively. to output node TOUT1 (e.g., to an input of amplifier 320). In the pseudo-differential architecture of thermometric segment 300 of FIG. 4A, the “1” entry for an element 401ₖ[0], 401ₖ[1] further indicates that its corresponding switch 414 or 415, as the case may be, is controlled to couple its resistor 412 or 413, respectively, to output node TOUT2 (e.g., at circuit ground). A “0” entry for an element in FIG. 5B indicates the opposite state, in which switch 404 or 405, as the case may be, is coupling its resistor 402 or 403, respectively. to output node OUT2, and that the corresponding switch 414 or 415, as the case may be, is coupling its resistor 412 or 413, respectively, to output node TOUT1. In other words, a “1” entry for an element in a slice 301 indicates that a positive current (from reference voltage +V_{ref}) is sourced for that element into the negative input of amplifier 320, and a “0” entry indicates a negative current (from reference voltage −V_{ref}) is sourced from that element into the negative input of amplifier 320.

At time n=0 in the example of FIG. 5B, the value V_{T}[0] of the T MSBs of DAC input code V[0] is 7. In this example in which each resistor in slices 301₁ through 301₁₆ has a resistance of 2R, switch logic 312 generates the appropriate switch control signals SCW to set the state of fourteen elements to the “1” state. In the example of FIG. 5B at time n=0, the fourteen elements having a “1” entry are the two elements in each of consecutive slices 301₁ through 301₇. In this embodiment, element 401₁[0] is the first element having a “1” entry, and is identified by a “start” pointer value Start[n]=1. The other elements with a “1” value follow element 401₁[0], indicated by the start pointer value Start[n]=1, in sequence from left to right in the table of FIG. 5B. In some embodiments, this start pointer value Start[n] is used in the rotation of “1” entries around the T slices 301₁ through 301_{T}.

According to some embodiments, the transition vector value K[n] is held to a constant value C over the DAC input code sample sequence. In the example of FIG. 5A, this value C=2. Other values of the constant C may be used. In some embodiments, such as that of FIGS. 5A through 5C, the sample rate of the DAC input codes is assumed to be oversampled relative to the analog output signal frequency so that the difference in the T MSBs V_{T}[n−1] and V_{T}[n] of successive DAC input codes is no more than one thermometer code level. In other words, the value of the T MSBs of DAC input code V_{T}[n] differs from that of the previous code V_{T}[n−1] only by −1, 0, or +1.

The example process of FIG. 5A begins with switch logic 312 receiving a DAC input code V[n] in process 502. In process 504, a difference ΔV_{T}[n] of the T MSBs V_{T}[n] relative to the T MSBs V_{T}[n−1] from the preceding sample is calculated. Decisions 505 and 507 are then executed to evaluate the difference ΔV_{T}[n] as −1, 0, or +1, based upon which a quantity Jump[n] can be determined. In these embodiments, the quantity Jump[n] is calculated based on the current value V_{T}[n] and the value of C, in order to maintain a constant transition vector value K[n] while also rotating the switch positions through slices 301.

In the example of FIG. 5A, decision 505 first determines whether difference ΔV_{T}[n]=0. If so (decision 505 returns “yes”), quantity Jump[n] is set, in process 506, to a random value r[n] taking one of the values of +1 or −1 from process 509. For example, switch logic 312 or other circuitry in DAC 150 may execute a pseudo-random number generator (PRNG) according to a white noise or shaped noise characteristic in process 509. If difference ΔV_{T}[n]≠0 (decision 505 returns “no”), switch logic 312 executes decision 507 to determine whether difference ΔV_{T}[n]=+1. If so (decision 507 returns “yes”), the quantity Jump[n] is set, in process 508, to the random value r[n] from process 509 minus 1 (e.g., r[n]−1). If difference ΔV_{T}[n]≠+1 (decision 507 returns “no”), then difference ΔV_{T}[n]=−1. In this case, switch logic 312 sets the quantity Jump[n], in process 510, to the random value r[n] from process 509 plus 1 (e.g., r[n]+1). Following the calculation of the quantity Jump[n] for the current DAC input code V[n] in one of processes 506, 508, 510, switch logic 312 increments, decrements, or maintains the start pointer value Start[n] according to the quantity Jump[n], in process 512.

Meanwhile in process 511, a thermometric code value is encoded based on the T MSBs V_{T}[n] of the current DAC input code V[n]. In this embodiment, referring to FIG. 5B, the thermometric code is arranged as a sequence of consecutive “1” entries corresponding to the value V_{T}[n], with all other entries having a “0” value. In process 514, switch logic 312 applies switch control signals to switches 404, 405, 414, 415 in thermometric slices 301 according to the thermometric code value encoded in process 511, the consecutive “1” entries of the thermometric code are assigned to elements 401 in slices 301 beginning with the location indicated by the start pointer value Start[n].

FIG. 5B illustrates an example of the process of FIG. 5A, for the example in which each slice 301 includes two elements 401. As noted above, at time n=0, the value V_{T}[0] of the T MSBs of DAC input code V[0] is 7 and thus fourteen (2×7) of the elements of slices 301₁ through 301₁₆ are set to the “1” state, beginning with element 401₁[0] of slice 301₁ as indicated by the start pointer value Start[n]=1. More generally where each slice 301 includes M elements 401, the number of elements set to the “1” state is M times the value V_{T}[n] of the T MSBs of the input code.

At time n=1, the next input code V[1], having a value V_{T}[1] of 8 in its T MSBs, is received in process 502 in the process of FIG. 5A. In process 504, the difference ΔV_{T}[1]=+1 is determined, such that decision 505 returns a “no” and decision 507 returns a “yes”. In process 508, the quantity Jump[1] for the current DAC input code V[1] is calculated. In the example of FIG. 5B, the random number value is r[1]=−1, such that the quantity Jump[1]=(−1)−1=−2. In process 512, the start pointer value Start[0] is decremented by the quantity Jump[1]=−2, to the value Start[1]=31 (wrapping around the elements of slices 301), pointing to element 401₁₆[0] of slice 301₁₆. Because the current value V_{T}[1]=8, sixteen elements of slices 301 are set to “1”, beginning from the location indicated by the start pointer value Start[1]. As a result, the number of changed entries at time n=1 from time n=0 is two, namely the two entries for slice 301₁₆. Thus the value of transition vector K[1]=2.

At time n=2, the next received value V_{T}[2] is 7, such that the difference ΔV_{T}[2]=−1. Both of decisions 505 and 507 return a “no”. In process 510, the quantity Jump[2] is calculated, using a random number value r[1]=+1 in this example, such that the quantity Jump[2]=(+1)+1=+2. In process 512, the start pointer value Start[1] is incremented by the quantity Jump[2]=+2, to the value Start[2]=1 (again wrapping around the elements of slices 301), pointing to element 401₁[0] of slice 301₁. For the current value V_{T}[2]=7, fourteen elements of slices 301 are set to “1”, beginning from the location indicated by the start pointer value Start[2]. Again, the number of changed entries at time n=2 relative to time n=1 is two, namely the two entries for slice 301₁₆ (from “1” to “0”). The value of transition vector remains constant, at K[2]=2.

The next received value V_{T}[3] at time n=3 remains at the value 7 in this example, such that the difference ΔV_{T}[3]=0 and decision 505 returns a “yes”. The quantity Jump[3] is calculated in process 510, using a random number value r[3]=+1 in this example, such that the quantity Jump[3]=+1. In process 512, the start pointer value Start[2] is incremented by the quantity Jump[3]=+1, to the value Start[3]=2, pointing to element 401₁[1] of slice 301₁. The current value V_{T}[3]=7 maintains fourteen elements of slices 301 as set to “1”, beginning from the location indicated by the new start pointer values Start[3]. At time n=3, the value of transition vector K[3]=2, corresponding to changes at the first entry of slice 301₁ (from “1” to “0”) and the first entry of slice 301₈ (from “0” to “1”).

At time n=4, the received value V_{T}[4]=6. According to the process of FIG. 5A, process 504 computes the difference ΔV_{T}[4]=−1, and both of decisions 505 and 507 return a “no”. The quantity Jump[4] is calculated in process 508, in this case with random number value r[4]=+1, resulting in quantity Jump[4]=(+1)+1=+2. In process 512, the start pointer value Start[3] is incremented by the quantity Jump[4]=+2, to the value Start[4]=4, pointing to element 401₂[0] of slice 301₂. The current value V_{T}[4]=6 corresponds to twelve elements of slices 301 as set to “1”, beginning from the location indicated by the new start pointer value Start[4]. Again, the value of transition vector K[4]=2 at time n=4, corresponding to changes at the second entry of slice 301₁ and the first entry of slice 301₂ (both from “1” to “0”).

The process of FIG. 5A continues in this manner for later samples DAC input code V[n]. By calculating the quantity Jump[n] based on the difference ΔV_{T}[n] of the current input code value V_{T}[n] relative to the previous input code values V_{T}[n−1], randomized by an amount based on the constant C of the transition vector K[n], the switch positions in the elements of slices 301 are rotated over the thermometric segment 300, while maintaining the constant transition vector K[n]=C.

FIG. 5C illustrates an architecture of switch logic 520 for implementing the operations of FIG. 5A for thermometric segment 300 according to some embodiments. For example, switch logic 520 according to the architecture of FIG. 5C may functionally be arranged as combinatorial or sequential logic, or a combination of the two, and physically implemented in the form of custom or semi-custom logic circuitry, programmable logic (e.g., a microprocessor or microcontroller in combination with program memory), or a combination thereof.

Switch logic 520 in these embodiments includes delay buffer 521 and adder 522, both having inputs receiving the T MSBs V_{T}[n] of DAC input code V[n] for the current (n^{th}) input code. Delay buffer 521 is clocked by the sample clock of the sample stream of DAC input codes V[n], and outputs the T MSBs V_{T}[n−1] from the previous input code to an input of adder 522. Adder 522 calculates the difference ΔV_{T}[n] between the values V_{T}[n] and V_{T}[n−1] (process 504 of FIG. 5A) and outputs that difference ΔV_{T}[n] to difference encoder 524.

Difference encoder 524 of switch logic 520 executes decisions 505 and 507 in the process of FIG. 5A. As shown in FIG. 5C, difference encoder 524 outputs a 2-bit binary code in response to the difference ΔV_{T}[n] determined by adder 522. In the embodiments of FIGS. 5A through 5C in which the sample rate of the DAC input codes is oversampled so that the difference ΔV_{T}[n] is no more than one thermometer code level, the set of possible values of difference ΔV_{T}[n] from adder 522 is {−1, 0, +1}. The 2-bit binary code output by difference encoder 524 in response to the value of difference ΔV_{T}[n] is applied to a select input of multiplexer 528.

Multiplexer 528 has four inputs in the example of FIG. 5C, three of which are coupled to outputs of multiplexers 526a, 526b, 526c, with the fourth receiving a 0 value (e.g., an error or other null event). Multiplexer 526a has one input receiving a +1 value and a second input receiving a −1 value; multiplexer 526b has one input receiving a 0 value and a second input receiving the value −2; and multiplexer 526c has one input receiving a 0 value and a second input receiving the value +2. Each of multiplexers 526a, 526b, 526c has a select input receiving a random bit value r_{b}[n], which takes either a 0 value or a 1 value and thus controls the selections of multiplexers 526a, 526b, 526c.

In this example, the operation of multiplexer 526a corresponds to process 506 of FIG. 5A, randomly determining the quantity Jump[n] as either +1 or −1 for the case in which difference ΔV_{T}[n]=0. For this case of difference ΔV_{T}[n]=0, difference encoder 524 outputs the binary value of 00 for diff_code[1:0], causing multiplexer 528 to select the output of multiplexer 526a as the quantity Jump[n].

Similarly, the operation of multiplexer 526b corresponds to process 508 of FIG. 5A, randomly determining the quantity Jump[n] as either 0 or −2 for the case in which difference ΔV_{T}[n]=+1. For this case of difference ΔV_{T}[n]=+1, difference encoder 524 outputs the binary value of 01 for diff_code[1:0], causing multiplexer 528 to select the output of multiplexer 526b as the quantity Jump[n].

Multiplexer 526c corresponds to process 510 of FIG. 5A, randomly determining the quantity Jump[n] as either 0 or +2 for a difference ΔV_{T}[n]=−1. In this case, difference encoder 524 outputs diff_code[1:0]=11, causing multiplexer 528 to select the output of multiplexer 526c as the quantity Jump[n].

According to some embodiments, shift logic 520 of FIG. 5C includes adder 530, modulo block 532, and delay buffer 533, for determining the start pointer value Start[n] for the current input code V[n], for example as described relative to process 512 of FIG. 5A. In these embodiments, the start pointer value Start[n] for the current input code is determined from the quantity Jump[n] at the output of multiplexer 528 and the start pointer value Start[n−1] for the previous sample. Adder 530 in shift logic 520 has one input receiving the quantity Jump[n] from the output of multiplexer 528, and a second input receiving the previous start buffer value Start[n−1] from an output of delay buffer 533. Adder 530 adds the quantity Jump[n] and the previous start buffer value Start[n−1], and outputs the sum as value sum_out to modulo block 532. Modulo block 532 outputs the current start pointer value Start[n] as the remainder from a modulo operation on the value sum_out, where the divisor is the number of elements in thermometric segment 300 (e.g., 32, for the example of FIG. 5B where T=16 and each slice 301 has two elements 401). The start pointer value Start[n] is applied to the input of delay buffer 533, which is clocked by the sample clock, and to a shift input of circular shifter 540. Circular shifter 540 may be constructed as a shift register in which stored data may be shifted according to a value received at the shift input, or as a register storing data that may be read out in sequence beginning with an index value applied at the shift input (e.g., without shifting the stored data in the register). In either case, circular shifter 540 is circular in the sense that its contents wrap around as shifted.

Thermometric encoder 530 in shift logic 520 according to some embodiments has an input receiving the T MSBs V_{T}[n] of DAC input code V[n]. Thermometric encoder 530 encodes a thermometer code value therm_code[n] based on the input code value V_{T}[n], as described above for process 511 of FIG. 5A. The encoding applied by thermometric encoder 530 is derived as appropriate for the architecture and number of elements 401 of thermometric segment 300. The thermometric code generated by encoder 530 is loaded into circular shifter 540 in this example. Circular shifter 540 assigns the “1” entries to the elements 401 by shifting the thermometer code value therm_code[n] according to the start pointer value Start[n] from modulo block 532. The output of circular shifter 540 presents switch control signals SCW_{T}[n] to the switches in slices 301₁ through 301_{T} of thermometric segment 300, to generate the appropriate current in response to the T MSBs V_{T}[n] of the current DAC input code V[n].

Certain modifications to the process and circuitry of shift logic 520 according to FIGS. 5A through 5C may be implemented in some embodiments. In some embodiments, the size of the shifter may be reduced to one-half that of the number of elements 401 in slices 301 to save chip area and execution time. In that arrangement, the shifting of the “1” entries for elements 401 may be performed in two operations, with the first half of the shifted contents stored in a buffer, and the shift repeated for the second half; a multiplexer may append a “0” or a “1” value according to the eventual LSB of the start pointer. In another arrangement according to some embodiments, ambiguities at the DAC input code extreme values of V_{T}[n]=0 or full-code (e.g., all T bits are “1”) are avoided by adding a digital offset of +1 to the DAC input code value V_{T}[n], and negating that addition by an “always-ON” element in the analog circuitry of thermometric segment 300. In some embodiments, two or more additional elements beyond those associated with the T slices 301₁ through 301_{T} may be included to ensure seamless rotation of the start pointer value. Furthermore, while the above-described embodiments are with reference to the value C=2 for transition vector K[n], the process of FIG. 5A and the architecture of switch logic shown in FIG. 5C can be readily modified for other transition vector values, and for four, eight, or other numbers of elements per slice 301.

According to some embodiments described above relative to FIGS. 4A through 4D and 5A through 5C, dynamic error in the form of harmonic distortion can be significantly reduced, due at least in part to maintaining a constant value of the transition vector, independent of the input code stream. Because this reduction in dynamic error can be attained by changes in only the switch configuration and the control circuitry of the DAC, minimal additional chip area is required over that of conventional resistive DACs, according to some embodiments. Improvement in error due to residual static mismatches can also be attained, by virtue of the inherent rotation of the conducting branches over the thermometric array.

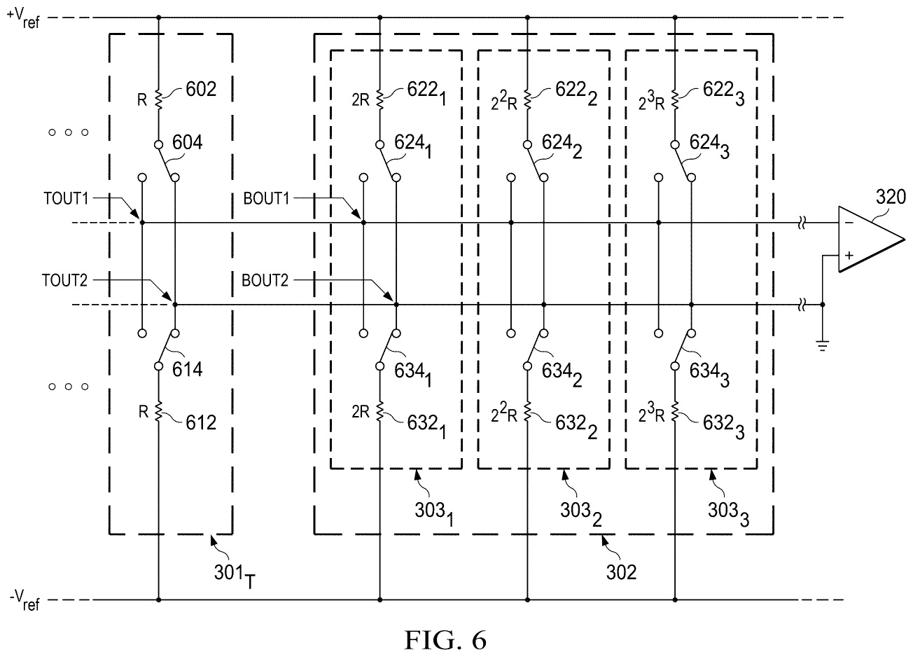

FIG. 6 schematically illustrates binary segment 302 in DAC 150, according to some embodiments. Binary segment 302 is shown in FIG. 6 as adjacent to the T^{th} slice 301_{T} of thermometric segment 300 of DAC 150. As described above relative to FIG. 1, binary segment 302 is arranged into B slices, each corresponding to one of the B upper least significant bits (ULSBs) of DAC input code V[n]. In this example, B=3, and as such binary segment 302 of FIG. 6 according to these embodiments includes three slices 303₁ through 301₃, each corresponding to one of three ULSBs of DAC input code V[n]. More or fewer binary slices 303 may be included in binary segment 302 according to these embodiments.

Thermometric slice 301_{T} is schematically illustrated in FIG. 6 as nominally including resistance 602 and switch 604 coupled in series to positive polarity reference voltage +V_{ref}, and resistance 612 and switch 614 coupled in series to negative polarity reference voltage −V_{ref}. For purposes of this description of binary segment 302, resistances 602, 612 in thermometric slice 301_{T} (and in all other thermometric slices) each have the nominal value R. In some embodiments, as described above, thermometric slice 301_{T} may be sub-segmented to include multiple elements of resistors and associated switches to attain the nominal resistance R (e.g., two elements with resistances 2R, four elements with resistances 4R, etc.).

Accordingly, given a nominal resistance R of thermometric slice 301_{T}, binary slice 301₁ includes resistance 622₁ of nominal value 2R coupled in series with switch 624₁ to positive polarity reference voltage +V_{ref}, and resistance 632₁ of nominal value 2R coupled in series with switch 634₁ to negative polarity reference voltage −V_{ref}. Binary slice 301₂ includes resistance 622₂ of nominal value 2²R coupled in series with switch 624₂ to positive reference voltage +V_{ref}, and resistance 632₂ of nominal value 2²R coupled in series with switch 634₂ to negative reference voltage −V_{ref}. Binary slice 301₃ similarly includes resistance 622₃ of nominal value 2³R coupled in series with switch 624₃ to reference voltage +V_{ref}, and resistance 632₃ of nominal value 2³R coupled in series with switch 634₃ to reference voltage −V_{ref}. The nominal resistances of any additional binary slices 301 in binary segment 302 increase by powers of two, in a similar manner.

Switches 624, 634 are controlled by a corresponding switch control signal SCW from switch logic 312 to couple their corresponding resistance 622, 632, respectively, to binary output nodes BOUT1, BOUT2. Binary output node BOUT1 is coupled to the negative input of amplifier 320, and binary output node BOUT2 is coupled to circuit ground (e.g., via ground buffer 330), or to the positive input of amplifier 320. In the segmented architecture of DAC 150, binary output nodes BOUT1, BOUT2 are coupled to thermometric output nodes TOUT1, TOUT2, respectively.

For binary segment 302, the encoding of the B ULSBs of DAC input code V[n] is a binary encoding, in contrast to the thermometer code encoding for thermometric segment 300. Accordingly, because the values of resistances 622 and 632 increase by a factor of two from one binary slice 303ₖ to the next least significant binary slice 303ₖ₊₁ as shown in FIG. 6, the resulting current conducted into binary output node BOUT1 decreases by a factor of two from slice to slice.

Even in embodiments in which harmonic distortion is reduced such as described above for thermometric segment 300, some residual non-linearity may be present due to signal harmonics in the transition vector of the ULSB bits implemented as binary segment 302. One can express an effective transition vector K_{B}[n] of 3-bit binary segment 302 for the B ULSBs V_{B}[n] of a given DAC input code V[n] as:

$${K}_{B} [ n ] = \frac{1}{2} {K}_{B 1} [ n ] + \frac{1}{4} {K}_{B 2} [ n ] + \frac{1}{8} {K}_{B 2} [ n ] \qquad ( 2 )$$

where K_{B1}[n], K_{B2}[n], K_{B3}[n] are the transition vectors for binary slices 303₁, 303₂, 303₃, respectively. Because the component values of the transition vector K_{B}[n] of equation (2) for binary segment 302 are weighted by bit position, the value of the binary transition vector K_{B}[n] is correlated to the input signal, thus leading to harmonic distortion from dynamic mismatches in the binary slices 303.

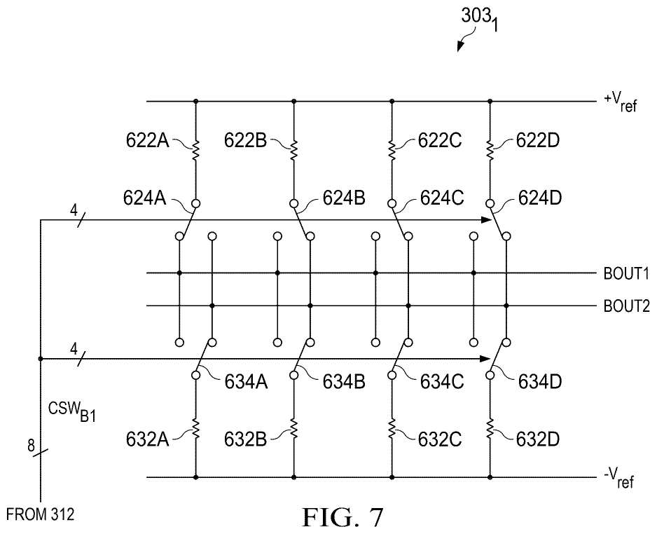

According to some embodiments, binary slices 303 are split into multiple redundant elements to enable rotation among those elements to maintain transition vector K_{B}[n] at a constant value K_{B}[n]=J independently of the value of DAC input code V[n], and thus reducing a source of harmonic distortion. FIG. 7 illustrates the construction of binary slice 303₁, according to some embodiments. The other binary slices 303₂, 303₃, etc. are similarly constructed as slice 303₁ of FIG. 7, but with different resistance values as described above.

In the example of FIG. 7, binary slice 303₁ includes four resistors 622A, 622B, 622C, 622D (collectively or generically referred as resistors 622), each coupled to positive polarity reference voltage +V_{ref}. Switches 624A, 624B, 624C, 624D (collectively or generically referred to as switches 624) are coupled on one side to corresponding resistors 622A, 622B, 622C, 622D, respectively. Switches 624 may be constructed similarly as switch 404 of FIG. 4C described above. Each switch 624 is independently controlled by switch control signals from switch logic 312 to couple its associated resistor 622 to one of output nodes BOUT1, BOUT2. Similarly, binary slice 303₁ also includes four resistors 632A, 632B, 632C, 632D (collectively or generically referred to as resistors 632), each coupled between negative polarity reference voltage −V_{ref} and a corresponding one of switches 634A, 634B, 634C, 634D (collectively or generically referred to as switches 632), respectively. Switches 634 may be constructed similarly as switch 414 of FIG. 4C described above. Each switch 634 is also independently controlled by switch control signals from switch logic 312 to couple its associated resistor 632 to one of output nodes BOUT1, BOUT2. As noted above, switches 624 are controlled independently (e.g., not necessarily in a complementary fashion) from switches 634.

According to some embodiments, resistors 622 and resistors 632 each have the nominal resistance 2R of slice 303₁. Similarly, resistors in similarly constructed slices 303₂ and 303₃ each have the nominal resistance 2²R and 2³R, respectively, of those slices. As a result, only one of resistors 622 and 632 in slice 303₁ is coupled to output node BOUT1 for any given input code value, with that resistor 622 or 632 providing the current corresponding to the reference voltage |V_{ref}|/2R.

In the example shown in FIG. 7, corresponding to a “1” at the bit position in DAC input code V[n] corresponding to binary slice 303₁, one of switches 624, for example switch 624A, receives a switch control signal from switch logic 312 causing it to couple resistor 622A to output node BOUT1. All of the other switches 624 and 634 receive switch control signals causing them to couple their corresponding resistors 622 and 632 to output node BOUT2. A positive current +V_{ref}/2R is thus conducted to output node BOUT1 in this example. Conversely, in response to a “0” at the bit position in DAC input code V[n] corresponding to binary slice 303₁, one of switches 634, for example switch 634A, is controlled by the corresponding switch control signal to couple its resistor 632A to output node BOUT1; all other switches 624 and 634 receive switch control signals causing them to couple their corresponding resistors 622 and 632 to output node BOUT2.

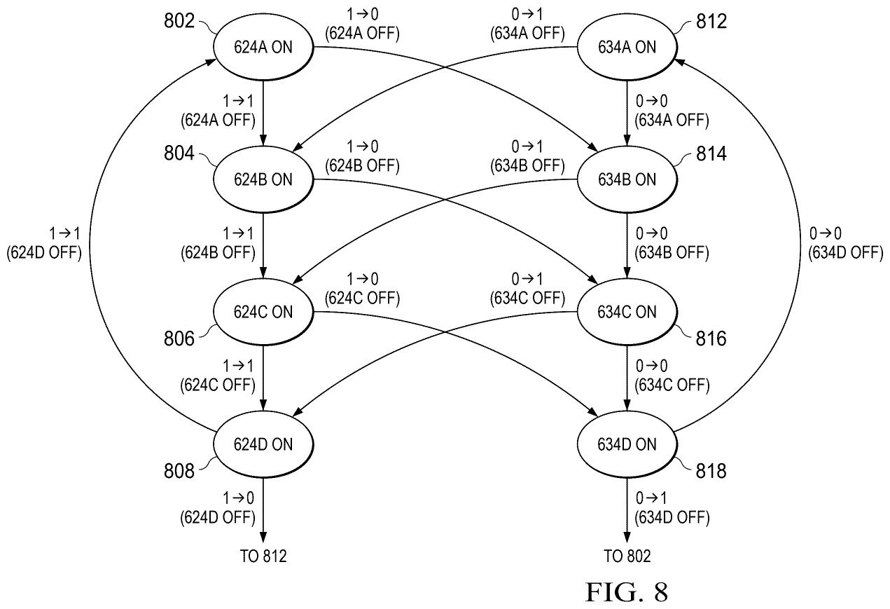

According to some embodiments, switch logic 312 is configured to control switches 624 and 634 in each binary slice 303 according to a pattern that rotates the one of switches 624, 634 that couples its resistor 622, 632, respectively, to output node BOUT1 in each DAC input code V[n]. FIG. 8 is an example state diagram of such rotation, according to some embodiments in which switch logic 312 is implemented as sequential logic for representative slice 303₁ of binary segment 302. In the alternative to sequential logic, switch logic 312 for binary segment 302 may be implemented as combinational logic, programmable logic executing program instructions stored in memory, or a combination thereof.

In the example of FIG. 8, a constant value J=2 of transition vector K_{B1}[n] is maintained for slice 303₁ over the sequence of DAC input codes V[n]. In the example of FIG. 8, this value J=2. For purposes of this description, the “on” state of a switch 624, 634 indicates selection of output node OUT1 for coupling to its corresponding resistor 622, 632; conversely, an “off” state of a switch 624, 634 indicates selection of output node OUT2 for coupling to its corresponding resistor 622, 632. Also, for purposes of this example description, a “1” state in the bit position of DAC input code V[n] corresponding to slice 303₁ (referred to as bit “B1”) indicates that one of switches 624A, 624B, 624C, 624D is on while the others, and all of switches 634A, 634B, 634C, 634D, are off. Conversely, a “0” state in the bit position of DAC input code V[n] corresponding to slice 303₁ indicates that one of switches 634A, 634B, 634C, 634D is on while the others, and all of switches 624A, 624B, 624C, 624D are off.

FIG. 8 illustrates an example sequence in which the one “on” state position rotates among switches 624, 634 of slice 303₁ of FIG. 7 in response to a sample sequence of DAC input code V[n]. Beginning for example at state 802, switch 624A is on in response to a “1” at bit B1 of DAC input code V[n]. All other switches 624, 634 are in the “off” state. According to this example, in which the constant value of transition vector K_{B1}[n]=2, two switches 624, 634 are to change state in response to the next DAC input code V[n+1] regardless of bit B1 being either a “0” or a “1”. In this example, in response to bit B1 of DAC input code V[n+1] being a “1”, a transition to state 804 from state 802 is performed by switch logic 312, turning off switch 624A and turning on switch 624B, and giving rise to a value of transition vector K_{B1}[n+1]=2. By selecting a different one of switches 624 to turn on in response to bit B1 not changing from one input code to the next, both a constant transition vector value is maintained, and also the “on” switch position is rotated among the redundant switches 624. As shown in FIG. 8, continued “1” values at bit B1 for additional DAC input codes will rotate the “on” switch in a sequence from switch 624A to switch 624B (state 804), to switch 624C (state 806), to switch 624D (state 808), and back to switch 624A (state 802). The constant value of transition vector K_{B1}[n]=2 is maintained throughout. The particular sequence in which switches 624, in this case, are turned on may vary from that shown in FIG. 8 (e.g., from switch 624A to switch 624C to switch 624B to switch 624D, etc.) while maintaining a constant transition vector value and also rotating through switches 624.

Conversely, beginning again from state 802, in response to bit B1 of DAC input code V[n+1] being a “0”, a transition to state 814 from state 802 is executed by switch logic 312 in this example, turning off switch 624A and turning on switch 634B. Indeed, any change from “1” to “0” in bit B1 will necessarily give rise to a transition vector value K_{B1}[n+1]=2, since one switch 624 must turn off and one switch 634 must turn on. Similarly, any change in bit B1 from “0” to “1” (e.g., the transition from state 814 to state 806 in FIG. 8) results in a transition vector value K_{B1}[n+1]=2, since one switch 634 must turn off and one switch 624 must turn on. According to some embodiments including the example of FIG. 8, switch logic 312 is configured to enforce a rotational pattern of the state transitions for bit B1 changing from “0” to “1” or from “1” to “0”, for example as shown in FIG. 8. Again, the particular sequence in which switches 624 and 634 are turned on and off in response to changing values of bit B1 may vary from that shown in FIG. 8 while maintaining a constant transition vector value and also rotating through switches 624 and 634. For example, bit B1 changing from “1” to “0” from state 802 could be performed by turning off switch 624A and turning on switch 634A (state 812), so long as the next state transition from state 812 in response to bit B1 changing from “0” to “1” turns on one of switches 624B, 624C, 624C (rather than switch 624A again).

And again, a continuing sequence of “0” values at bit B1 for additional DAC input codes rotates the “on” switch in a sequence from switch 634A to switch 634B (state 814), to switch 634C (state 816), to switch 634D (state 818), and back to switch 634A (state 812). The constant value of transition vector K_{B1}[n]=2 is maintained throughout such a sequence, while rotating the “on” state among switches 634.

According to these embodiments, the redundancy provided by the multiple resistors 622 and 632 and the multiple corresponding switches 624 and 634 enables switch logic 312 to maintain a constant transition vector value K_{Bk}[n] for each slice 303ₖ of binary segment 302, independent of the values of DAC input code V[n]. As a result, the value of transition vector K_{B}[n] for binary segment 302 as a whole remains constant, independent of the input signal, which reduces harmonic distortion in the analog output signal from DAC 150. Furthermore, this redundancy allows the resistor selection to rotate among the elements of each slice 303, reducing the effects of residual static mismatches.

In some DAC systems, pre-distortion is applied to the DAC input signal to correct non-linearities and harmonics in the analog output signal. The pre-distortions in the input signal in these systems are based on observed errors in the output signal relative to applied DAC input code.

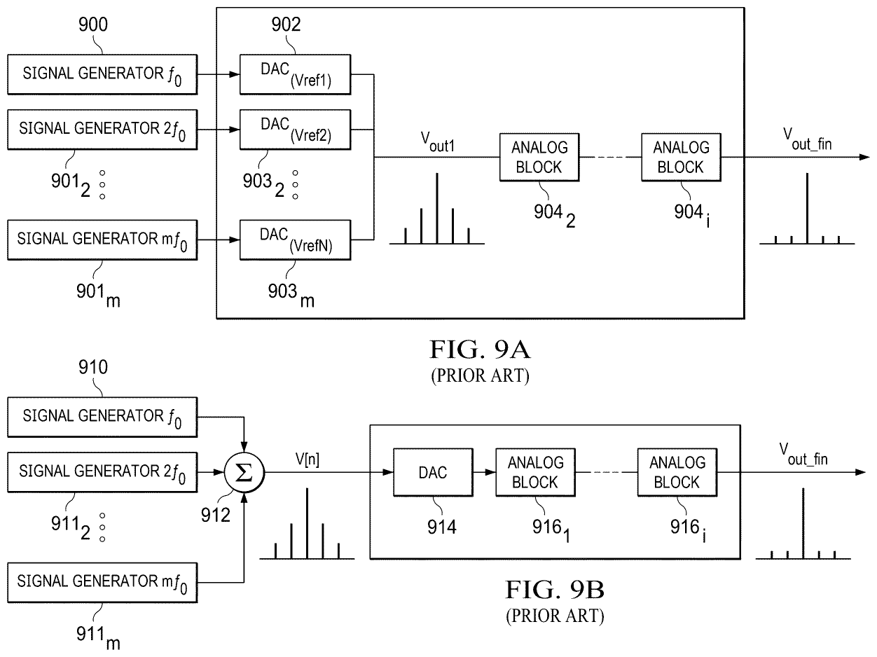

FIG. 9A illustrates a prior art example of generating and applying pre-distortion signals to the input signal, for example in connection with a DAC system for generating an analog sinusoidal signal. In this approach, signal generator 900 generates a stream of digital codes for generating the desired sinusoidal at a fundamental frequency f₀. Multiple signal generators 901₂ through 901ₘ generate streams of digital codes for adding pre-distortion signals at frequencies 2f₀ through mf₀, corresponding to the second through m^{th} harmonics of the fundamental frequency f₀. These pre-distortion signals each have an amplitude and phase selected to cancel or compensate for observed harmonic distortion in the analog output signal V_{out_fin}. The digital streams from signal generators 900 and 901₂ through 901ₘ are at a sample rate at least twice that of the highest harmonic frequency mf₀. In this prior art example, DACs 902 and 903₂ through 903ₘ receive the digital streams from signal generators 900 and 901₂ through 901ₘ as DAC input codes, and each generate a corresponding analog output signal. The analog output signals from DACs 902 and 903₂ through 903ₘ are summed (e.g., by applying the currents to an input of a current-to-voltage buffer, or by summing output voltages at a summing amplifier) to produce an analog voltage signal Vₒᵤₜ₁. Analog voltage signal Vₒᵤₜ₁ may be processed by one or more analog circuit blocks (e.g., filters, buffers or amplifiers, etc.) 904₂ through 904ᵢ to produce an analog output signal V_{out_fin}.

Another prior art example of generating and applying pre-distortion signals to the input signal is shown in FIG. 9B. In this example, signal generator 910 generates a stream of digital codes for generating the desired sinusoidal at its fundamental frequency f₀. Multiple signal generators 911₂ through 911ₘ generate digital code streams corresponding to harmonic frequencies 2f₀ through mf₀, respectively, at amplitudes and phases selected to cancel or compensate harmonic distortion observed in the analog output signal V_{out_fin}. In this prior art example, the digital signals from signal generators 910 and 911₂ through 911ₘ are applied to inputs of summing function 912, which digitally adds the streams to form a stream of DAC input codes V[n] for application to DAC 914. As in the example of FIG. 9A, the analog output from DAC 914 may be processed by one or more analog circuit blocks (e.g., filters, buffers or amplifiers, etc.) 9162 through 916; to produce an analog output signal V_{out_fin}.

Limitations in each of these prior art approaches of FIGS. 9A and 9B have been observed. The approach of FIG. 9A, in which the analog output signals from multiple DACs 902 and 903₂ through 903ₘ are added, requires both large chip area and also strict constraints on device matching among the multiple DACs. The approach of FIG. 9B, in which the outputs from signal generators 910 and 911₂ through 911ₘ are digitally added for application to DAC 914, has proven unable to attain the desired harmonic distortion reduction within the number of input bits (e.g., 18 to 20 bits) and thus within the resolution of DAC 914. The multiple digital signal generators 910 and 911₂ through 911ₘ also require significant added chip area.

Some embodiments overcome some or all of the issues of the prior art.

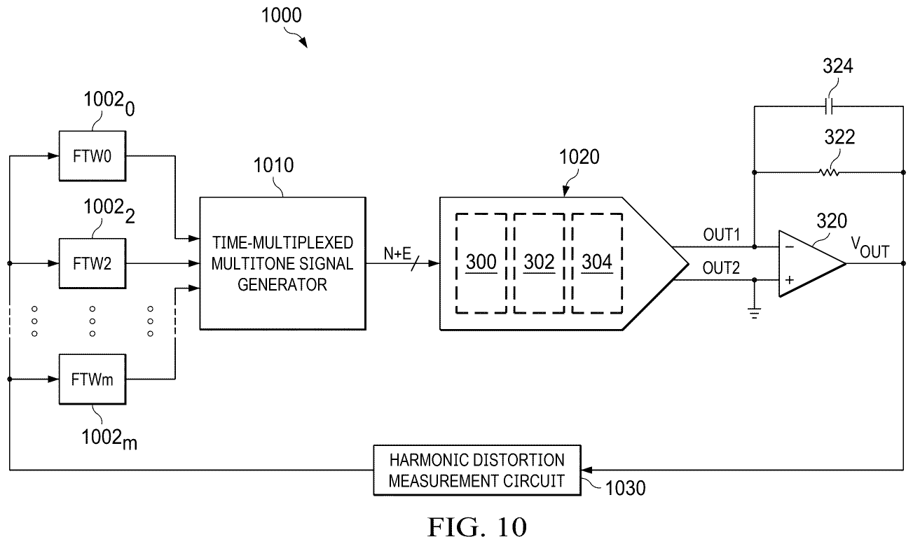

FIG. 10 illustrates DAC 1000, according to some mbodiments. DAC 1000 includes registers 1002₀ through 1002ₘ that store frequency tuning words (FTWs) for each of a number of frequencies. Each FTW includes information indicating the amplitude and phase of a frequency component in the desired analog output signal Vₒᵤₜ. In this example, register 1002₀ stores frequency tuning word FTW0 for the fundamental frequency f₀. For the case in which the desired analog output signal Vₒᵤₜ is a sinusoidal waveform, FTW0 indicates the amplitude and phase at the fundamental frequency. Register 1002₂ stores frequency tuning word FTW2, indicating the amplitude and phase of a correction signal at the second harmonic 2f₀ of the fundamental frequency. Additional registers 1002 are provided for higher-order harmonics, up to register 1002ₘ for the correction signal at the highest-order (m^{th}) harmonic mf₀ to be corrected.

In these embodiments, registers 1002 are coupled to inputs of time-multiplexed multitone signal generator 1010. Signal generator 1010 may be executed by digital processor 310 (FIG. 3), for example by its signal conditioning logic 314. As described in detail below, signal generator 1010 in these embodiments generate switch control signals corresponding to DAC input codes V[n] having more bits (e.g., N+E bits) than the specification N-bit width of DAC 100. The switch control signals for the N+E bit DAC input codes V[n] are forwarded to DAC array 1020, which includes thermometric segment 300, binary segment 302, and R-2R segment 304, for example arranged as shown in FIG. 3. As described above, segments 300, 302, 304 are coupled to output nodes OUT1 and OUT2. Output node OUT1 is coupled to the negative input of current-to-voltage buffer amplifier 320, while output node OUT2 is coupled to circuit ground (e.g., via a ground buffer in some embodiments) and to the positive input of amplifier 320. Feedback resistor 322 and capacitor 324 are coupled in parallel between the output and negative input of amplifier 320. The output of amplifier 320 at terminal VOUT presents analog output signal Vₒᵤₜ to downstream circuits (e.g., circuit 130 of FIG. 1), and to an input of harmonic distortion measurement circuit 1030.

In some embodiments, harmonic distortion measurement circuit 1030 monitors analog output signal Vₒᵤₜ from amplifier 320 to identify distortion at the harmonic frequencies 2f₀, 3f₀, . . . , mf₀, and to load registers 1002₂ through 1000ₘ with frequency tuning words FTW2 through FTWm indicating amplitude and phase of correction signal components at those frequencies based on the identified output distortion. In some examples, harmonic distortion measurement circuit 1030 may also include circuitry for identifying static corrections, for example as may be applied in DAC 1000 by way of trim DACs and the like (e.g., as shown in FIG. 2).

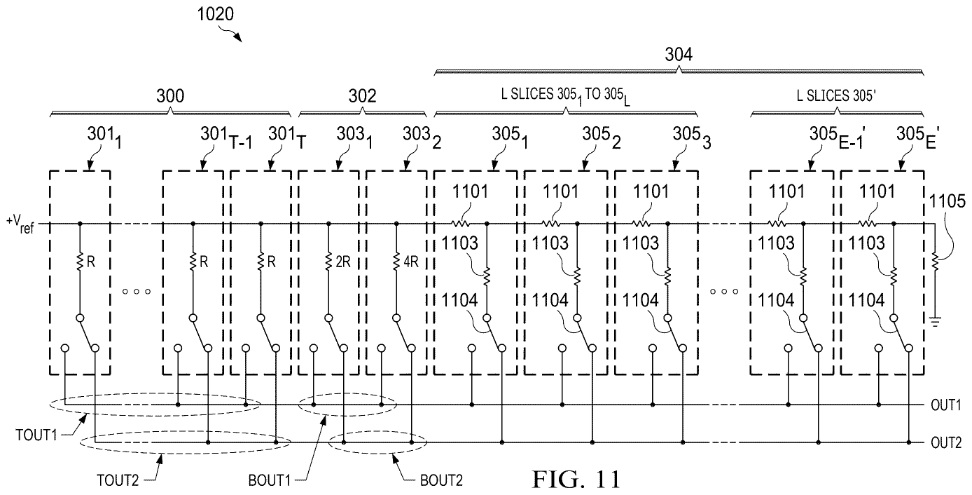

FIG. 11 illustrates an arrangement of DAC array 1020, according to some embodiments. In this arrangement, thermometric segment 300 of DAC array 1020 includes T slices 301₁ through 301_{T} (corresponding to the T MSBs of N-bit DAC input codes V[n]). In this example, binary segment 302 includes slices 303₁ and 303₂ of binary segment 302 (corresponding to B=2 ULSBs of N-bit DAC input codes V[n]; binary segment 302 may alternatively include more (or fewer) binary slices 303. R-2R segment 304 of DAC array 1020 includes L slices 305₁, 305₂, 305₃, etc. (corresponding to the L LSBs of N-bit DAC input codes V[n], where the numbers T+B+L=N. Additionally, R-2R segment 304 includes E additional slices 305′, including slices 305_{E-1}′ and 305_{E}′ shown in the example of FIG. 11. The number of these additional slices 305′ may vary according to the implementation. In one example, E=6 additional slices 305′ are included in DAC array 1020. As described above, these additional slices 305′ beyond the bit-width N of DAC 1000 are controlled from time-multiplexed multitone signal generator 1010 to further correct harmonic distortion at the output.

For simplicity, the schematic diagram of FIG. 11 shows each slice 301, 303 is shown as a single-resistor element with a single switch, selectively coupling its resistor to either output node OUT1 or output node OUT2. In some embodiments, thermometric slices 301 are constructed to include redundant elements, as described above in connection with FIGS. 3 through 5C. In some embodiments, binary slices 303 are constructed to include redundant elements, as described above in connection with FIGS. 6 through 8.

Also for simplicity, DAC array 1020 is shown in FIG. 11 as biased from a single reference voltage, in this example positive polarity reference voltage +V_{ref}. In some embodiments, DAC array 1020, including thermometric slices 301, binary slices 303, and R-2R segments 305, 305′ are arranged in a pseudo-differential architecture as described above, and in the above-incorporated U.S. application Ser. No. 18/814,694.

Referring to FIG. 11, each of thermometric slices 301₁ through 301_{T} has a nominal resistance R, whether as single resistors of resistance R, as two redundant parallel resistors of resistance 2R each, four parallel resistors of resistance 4R each, etc. Accordingly, the first binary slice 303₁ has a nominal resistance 2R (e.g., twice the nominal resistance R of a thermometric slice 301), and second binary slice 303₂ has a nominal resistance 4R, twice that of its next most significant binary slice 303₁. Any additional less significant binary slice 303ₖ will have twice the nominal resistance of its next most significant binary slice 303ₖ₋₁.

R-2R slice 305₁ includes resistors 1101, 1103. Resistor 1101 is coupled on one side to reference voltage +V_{ref} and another side to resistor 1103 and to a resistor 1101 in the next R-2R slice 305₂. Resistor 1101 has a resistance one-half that of the nominal resistance of the lowest-order binary slice 303₂. In the example of FIG. 11 in which slice 303₂ has a nominal resistance of 4R, resistor 1101 has a resistance of 2R. Resistor 1103 has a resistance 4R, twice the resistance of resistor 1101 in its slice 301₁, which in this case is a resistance of 4R. Resistor 1103 is coupled to switch 1104, which selectively couples slice 305₁ to either output node OUT1 or output node OUT2.

R-2R slices 305₂, 305₃, etc., and slices 305_{E-1}′, 305_{E}′ each include a resistor 1101 of resistance 2R, resistor 1103 of resistance 4R, and a switch 1104, arranged similarly as slice 305₁. Slice 305₂ is coupled to slice 305₁, slice 305₃ is coupled to slice 305₂, etc. in sequence through slice 305_{E}′ in this example. Terminating resistor 1105, of resistance 4R, is coupled between last slice 305_{E}′ and circuit ground. In this arrangement of R-2R segment 304, the current conducted from reference voltage +V_{ref} by a given slice 305 is one-half that of the next most significant slice 305 (or slice 303₂ for the case of slice 305₁). The current from a slice 305 is conducted to output node OUT1 or output node OUT2 in response to the state of the bit of DAC input code V[n] associated with that slice 305. On the other hand, the current from one of the E slices 305′ is conducted to output node OUT1 or output node OUT2 in response to the state of the corresponding one of the E extended bits as generated by time-multiplexed multitone signal generator 1010, based on frequency tuning words FTW₂ through FTWₘ. As noted above, further reduction in harmonic distortion can be attained by providing and controlling currents from the additional E slices 305′ beyond the N-bit bit width of DAC 1000, according to these embodiments.

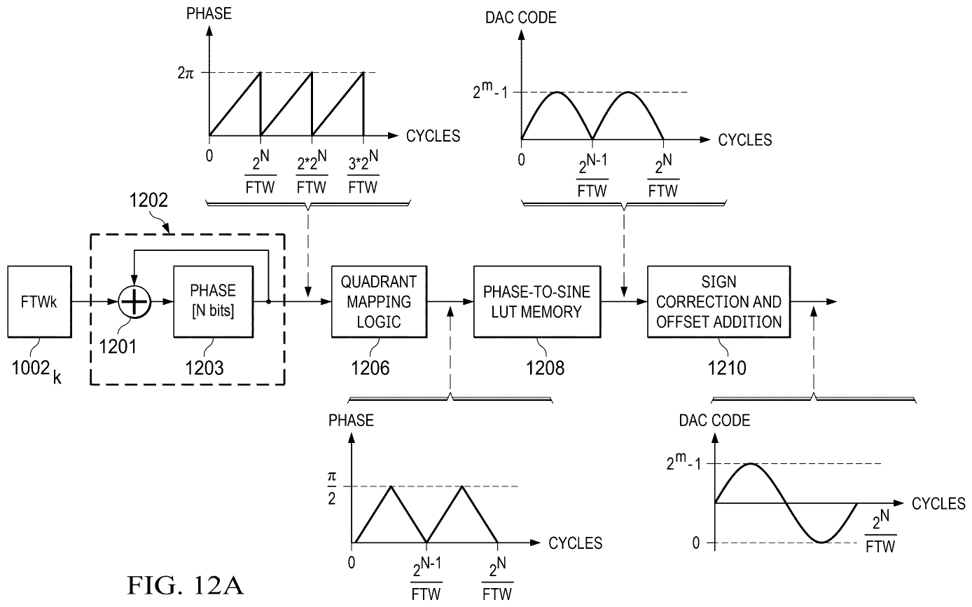

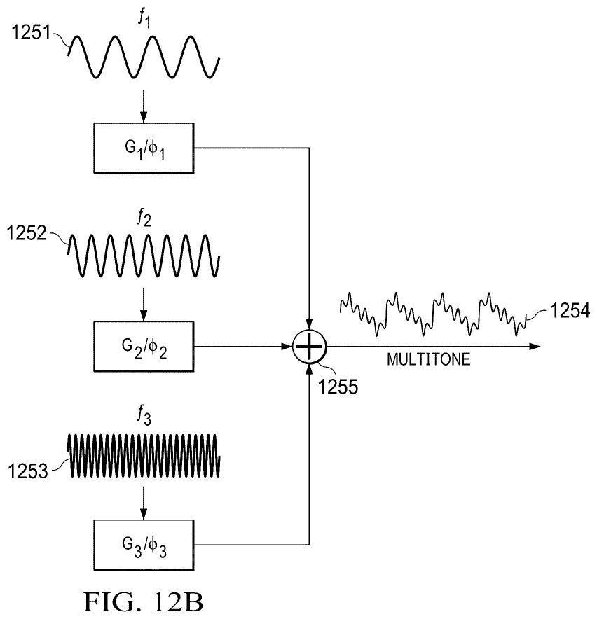

FIG. 12A functionally illustrates the generating of one tone k of a correction signal based on a frequency tuning word FTWk for that tone k, in time-multiplexed multitone signal generator 1010 according to some embodiments. The arrangement of FIG. 12 corresponds to a direct digital frequency synthesis (DDFS) architecture. Register 1002ₖ stores FTWk for tone k, and applies FTWk to one input of adder 1201 in phase accumulator 1202. Adder 1201 adds the value of FTWk to an accumulated phase value stored, as an N bit value, in phase buffer 1203. In this example, any overflow beyond the value 2π in the accumulated phase value simply wraps around. The output of phase accumulator 1202 thus has a linear sawtooth characteristic as shown in FIG. 12, advancing from 0 to 2π over each interval of 2^{N}/FTWk cycles.

The output of phase accumulator 1202 is applied to quadrant mapping logic 1206. Quadrant mapping logic 1206 maps the accumulated phase values from phase accumulator to a range from 0 to π/2 over four quadrants of each interval of 2^{N}/FTWk cycles, applying the symmetry of the sine waveform. The output of quadrant mapping logic 1206 thus corresponds to a triangle waveform at twice the frequency of the sawtooth waveform from phase accumulator 1202.

The output of quadrant mapping logic 1206 is applied to phase-to-sine look-up table (LUT) memory 1208. LUT memory 1208 is arranged as a memory resource for which each value output by quadrant mapping logic 1206 addresses a value in LUT memory 1208 representative of a point along a rectified sinusoid at the same frequency as the triangle waveform from quadrant mapping logic 1206, as shown in FIG. 12. LUT memory 1208 may output this sinusoid as a stream of M-bit samples, where M represents a larger number of bits than the N bits of FTWk. For example, M may equal N+E, where E is the number of extended slices 305′ in DAC array 1020.

Sign correction and offset addition logic 1210 generates digital values following a full sinusoidal waveform from the rectified sinusoid output by LUT memory 1208, with an offset added according to the desired DC level of the sinusoid. The sinusoid presented by the stream of DAC input codes output by sign correction and offset addition logic 1210 has a period corresponding to the interval of 2^{N}/FTWk cycles.

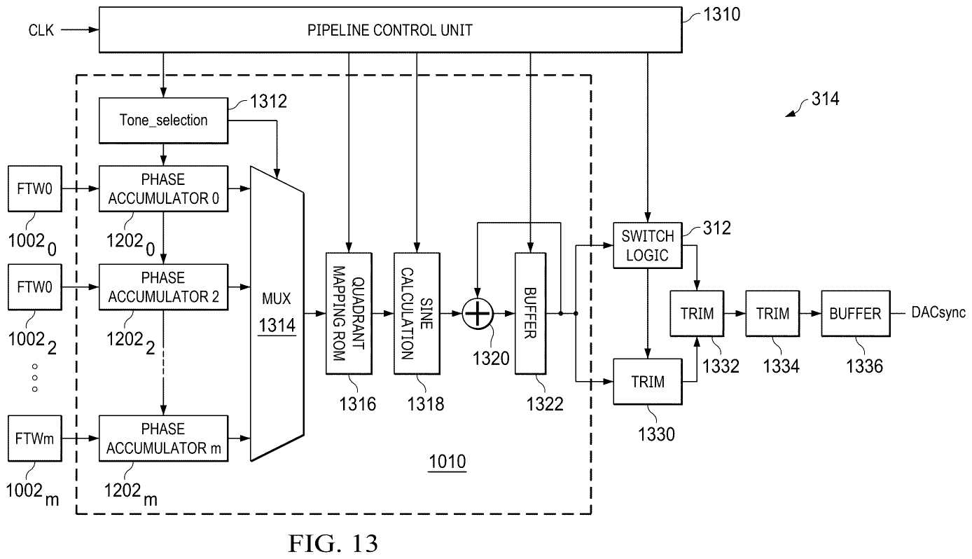

FIG. 12B is an illustrative example of multitone signal generation, such as implemented by pipelined time-multiplexed multitone signal generator 1010 according to some embodiments. In the example of FIG. 13A, a multitone signal may be generated as a weighted sum of three signals 1251, 1252, 1253 of different frequencies, amplitudes, and phases. In this example, signal 1251 is generated at frequency f₁, gain G₁, and phase φ₁, for example by a DDFS approach such as described in connection with FIG. 12A. Signals 1252 and 1253 are similarly generated by way of DDFS, with signal 1252 at frequency f₂, gain G₂, and phase φ₂, and signal 1253 at a frequency f₃, gain G₃, and phase φ₃. In this example, frequency f₂ is higher than frequency f₁ (e.g., at a second harmonic) and frequency f₃ is higher than frequency f₂ (e.g., at an m^{th} harmonic, m>2). The three signals 1251, 1252, 1253 are summed at operator 1255 to produce multitone signal 1254. For the example of signal 1304 with the waveform shown in FIG. 13A, gain G₁ is 0.5 and gains G₂ and G₃ are both 0.25.

As noted above in connection with prior art FIG. 9B, generation of multitone signal 1304 using multiple digital signal generators 910 and 911₂ through 911ₘ comes at a cost of significant additional chip area. According to some embodiments, pipelined time-multiplexed multitone signal generator 1010 of DAC 1000 shown in FIG. 10 avoids this additional cost by digitally generating a multitone signal, for application to DAC array 1020, in a time-multiplexed and pipelined manner.

FIG. 13 illustrates the architecture of signal conditioning circuit 314 of FIG. 3 incorporating pipelined time-multiplexed multitone signal generator 1010, according to some embodiments. In this architecture, signal generator 1010 has inputs coupled to registers 1002₀ through 1002ₘ. In contrast to the multiple digital signal generators of FIG. 9B, signal generator 1010 according to some embodiments include phase accumulators 1202₀ through 1202ₘ, each receiving frequency tuning words FTW₀ through FTWₘ, respectively, from registers 1002₀ through 1002ₘ. Phase accumulators 1202₀ through 1202ₘ have outputs coupled to corresponding inputs of multiplexer 1314. Multiplexer 1314 has a control input coupled to an output of tone selection circuit 1312, and has an output coupled to an input of quadrant mapping logic 1316. Quadrant mapping logic 1316 may be implemented as logic circuitry, or as, e.g., a read-only memory (ROM) (e.g., as a look-up table).

According to some embodiments, pipeline control unit 1310 controls the timing of various circuits and functions in signal generator 1010. Pipeline control unit 1310 may be implemented as logic circuitry, for example combinational, sequential, or programmable logic circuitry operating synchronously with a clock signal CLK from clock circuitry (not shown) in DAC 1000. As shown in FIG. 13, pipeline control unit 1310 clocks tone selection circuit 1312 to initiate a phase accumulation cycle by phase accumulators 1202₀ through 1202ₘ, and to control multiplexer 1314 to select, also in sequence, the outputs of phase accumulators 1202₀ through 1202ₘ for forwarding to quadrant mapping logic 1316.

Quadrant mapping logic 1316 maps the accumulated phase at its input from a sawtooth waveform shape to a triangle waveform, as described in the DDFS approach of FIG. 12A. The output of quadrant mapping logic 1316 is applied to an input of sine calculation circuit 1318, which performs the functions of sine LUT 1208 (conversion of the triangle waveform to a rectified sinusoid) and sign correction and offset addition 1210, both as described above in connection with FIG. 12A. The output of sine calculation circuit 1318 is coupled to an input of adder 1320. In some embodiments, the output of sine calculation logic 1318 is in the form of an N+E bit digital word, extending the bit width of the sinusoid sample value by E bits beyond the N-bit specified resolution of DAC 1000 (e.g., as indicated by N-bit width of frequency tuning words FTW₀ through FTWₘ). These E bits correspond to the E slices 305′ of R-2R segment 304 of DAC array 1020 (FIG. 11).

Time-multiplexing of the tones represented by frequency tuning words FTW₀ through FTWₘ results from the sequenced application of phase accumulators 1202₀ through 1202ₘ by multiplexer 1314. Because the accumulated phases from phase accumulators 1202₀ through 1202ₘ are sequentially applied, sine calculation circuit 1318 is processing a sinusoid value for one tone while quadrant mapping logic 1316 is processing the accumulated phase for the next tone in the sequence.

Adder 1320 has an output coupled to an input of buffer 1322, and an output of buffer 1322 is coupled to a second input of adder 1320. Accordingly, adder 1320 and buffer 1322, under the control of pipeline control unit 1310, accumulate one instance of a calculated sine value for each of the tones corresponding to frequency tuning words FTW₀ through FTWₘ. Additional calculation, for example as appropriate for generating a correct sinusoid, may be performed in connection with buffer 1322 as appropriate. This accumulation of a calculated sine value for each of the tones thus generates one sample of a digital multitone signal (e.g., multitone signal 1254 of FIG. 12B). The output of buffer 1322 is coupled to switch logic 312 and to trim function 1330.

In some embodiments, signal generator 1010 is clocked at a rate that is higher by at least a factor of m faster than the sampling frequency of the DAC input codes V[n], to attain the time-multiplexing and pipelined generation of the digital multitone signal. For the example of an eight tone multitone signal, signal generator 1010 must be clocked at a rate at least 8× (e.g., 10×) the DAC input code sample frequency.

In the example architecture of FIG. 13, switch logic 312 generates the appropriate switch control signals SCW for switches in thermometric segment 300 and binary segment 302, for example according to the embodiments described above in connection with FIGS. 6B and 8. In some embodiments, trim circuit 1330 may apply the output of a trim DAC (not shown) to the least significant bits of the multitone sample corresponding to R-2R segment 304, for example to correct for intersymbol interference (ISI). Additional trim stages 1332, 1334 may follow switch logic 312 and trim stage 1330, for example to apply corrections from trim DACs (not shown) to correct for static mismatch and other trim-correctable error (e.g., similar to FIG. 2B). The output of the final trim stage 1334 is applied to output buffer 1336, which stores the corrected multitone signal sample for application to DAC array 1020, for example synchronously with a clock signal DACsync at the sample frequency of DAC input codes V[n].

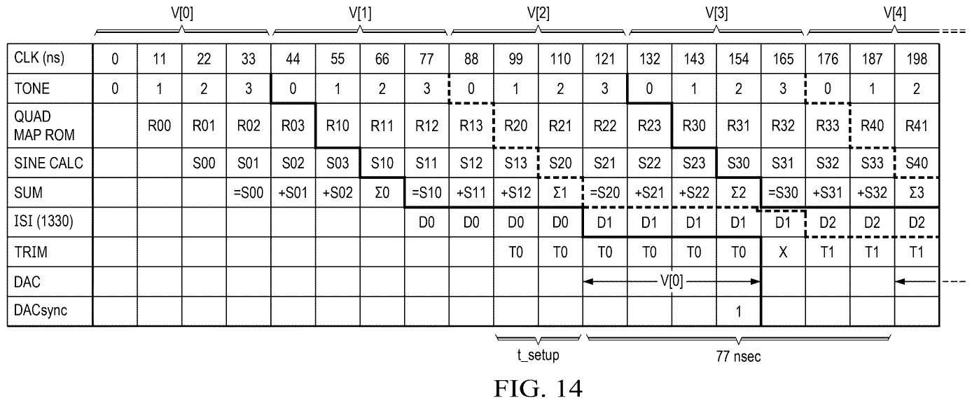

FIG. 14 illustrates an example of the operation of signal conditioning circuit 314 of FIG. 13, including pipelined time-multiplexed multitone signal generator 1010, according to some embodiments. According to this example, signal generator 1010 generates four tones, for example a fundamental tone at frequency f₀ and second through fourth harmonics of that tone, at frequencies 2f₀, 3f₀, 4f₀. Accordingly, signal generator 1010 operates at a clock rate (e.g., of clock CLK in FIG. 13) at least four times that of the sample rate of DAC input codes V[n]. In the example of FIG. 14, this oversampling at signal generator 1010 is 7× the sample rate of DAC input codes V[n], to allow adequate setup time at the input of DAC array 1020, and to provide a transition interval between successive codes. More specifically, as shown in FIG. 14, the period of clock CLK of signal generator 1010 is 11 nsec, while the sampling clock period of DAC input codes V[n] at DAC array 1020 is 77 nsec.

In some embodiments such as shown in FIG. 14, signal generator 1010 operates in six pipeline stages to time-multiplex digital values for the four tones in this example. Referring to FIGS. 13 and 14 in combination, the six pipeline stages in this example are:
Tone: selection of the output of one of phase accumulators 1202₀ through 1202ₘ by tone selection circuit 1312
Quad Map ROM: mapping of the sawtooth waveform from phase accumulators 1202 to a triangle waveform at quadrant mapping ROM 1316
Sine calc: applying the output of quadrant mapping ROM 1316 to sine calculation circuit (LUT) 1318
Sum: accumulating of sine values over the four tones at adder 1320 and buffer
ISI: operation of switch logic 312 and trim function 1330 for ISI correction
Trim: operation of trim stages 1332, 1334
   Each sample of the multitone signal (e.g., a DAC input code V[n]) output from trim stages 1332, 1334 is held in buffer 1336 for a number of cycles of clock CLK corresponding to a sample clock (clock DACsync) period at DAC array 1020.

By way of example, the pipelined time-multiplexed generation by signal generator 1010 of FIG. 13 of a DAC input code V[0] representative of a multitone signal, according to the embodiments, begins with phase accumulation of frequency tuning words FTW0 through FTWm by phase accumulators 1202₀ through 1202ₘ. This phase accumulation is clocked synchronously with the DAC input code (e.g., sample clock DACsync), for example controlled by pipeline control unit 1310. In the first cycle of CLK shown in FIG. 14 (at 0 ns), multiplexer 1314 selects the output of phase accumulator 1202₀ for the fundamental tone (tone 0). In the next CLK cycle (at 11 ns), quadrant mapping ROM 1316 outputs the mapped value R0 for tone 0 while, in the same CLK cycle, multiplexer 1314 selects the output of phase accumulator 1202₁ for tone 1 (e.g., the second harmonic tone). In the CLK cycle at 22 ns, the mapped value R0 for tone 0 is applied to sine calculation circuit 1318, outputting a value S0. Also in the CLK cycle at 22 ns, quadrant mapping ROM 1316 outputs the mapped value R1 for tone 1, and multiplexer 1314 selects the output of phase accumulator 1202₂ for tone 2 (e.g., a third harmonic). In the CLK cycle at 33 ns, the value S0 output by sine calculation circuit 1318 is stored (=S0) at buffer 1322 (buffer 1322 having been cleared from any prior DAC input code). Also in this CLK cycle at 33 ns, the mapped value R1 for tone 1 is applied to sine calculation circuit 1318, which outputs value S1, quadrant mapping ROM 1316 outputs the mapped value R2 for tone 2, and multiplexer 1314 selects the output of phase accumulator 1202₃ for tone 3 (e.g., a fourth harmonic).

In the CLK cycle at 44 ns, adder 1320 adds the value S1 from sine calculation circuit 1318 for tone 1 to the contents S0 in buffer 1322, accumulating the sine values for tones 0 and 1. Also in this CLK cycle at 44 ns, the mapped value R2 for tone 2 is applied to sine calculation circuit 1318, which outputs value S2, and quadrant mapping ROM 1316 outputs the mapped value R3 for tone 3. Processing of the next DAC input code value also begins in CLK cycle at 44 ns with multiplexer 1314 selecting the output of phase accumulator 1202₀ for the fundamental tone (tone 0) for this next DAC input code V[1].

This pipelined operation of signal generator 1010 continues for successive CLK cycles in the same manner. In CLK cycles at 55 ns and 66 ns, adder 1320 adds the values S2 and S3, respectively, to the accumulated sine values in buffer 1322, resulting in a sum Σ0 for DAC input code V[0] at the output of buffer 1322 in CLK cycle 66. Earlier pipeline stages (Sine Calc, Quad Map ROM, Tone) are processed for tones for the next DAC input code V[1] in these cycles. In the CLK cycles at 77 and 88 ns, the sum Σ0 for DAC input code V[0] is processed by switch logic 312 for the thermometric and binary segments and trim stage 1330 for the R-2R segment (value D0). Buffer 1336 retains and outputs (to DAC array 1020) the value T0 from trim stages 1332, 1334 for DAC input code V[0] in the CLK cycle beginning at 99 ns and extending for six CLK cycles in this example. The first two CLK cycles (77 and 88 ns) at which value T0 for DAC input code V[0] is retained and output by buffer 1336 provides an adequate setup time for DAC array 1020, which accepts value T0 beginning in the CLK cycle at 121 ns. In the CLK cycle at 154 ns, DAC array 1020 is clocked by clock DACsync.

As evident from these embodiments, the pipelined and time-multiplexed generation of a multitone correction signal, extending to additional LSBs beyond the data path bit width at the input of the DAC system, can be implemented in an efficient manner, without requiring multiple signal generator circuits. Excellent compensation of total harmonic distortion is enabled for high precision DACs.

As shown in FIG. 10, DAC 1000 according to some embodiments includes harmonic distortion measurement circuit 1030. In those embodiments, harmonic distortion measurement circuit 1030 includes a, e.g., precision, analog-to-digital converter (ADC) operating to periodically monitor the signal at output terminal VOUT to measure distortion at the various harmonic frequencies 2f₀ through mf₀. Based on those measurements, harmonic distortion measurement circuit can determine and adjust frequency tuning words FTW2 through FTWm for storing in registers 1002₂ through 1002ₘ, respectively. Based on those frequency tuning words FTW2 through FTWm, signal generator circuit 1010 according to some embodiments generates correction signal components at the corresponding harmonic frequencies, as described above. Closed-loop correction for harmonic distortion can be provided in such embodiments.

In some embodiments, frequency tuning words FTW2 through FTWm for the correction of harmonic distortion at corresponding harmonic frequencies 2f₀ through mf₀ are determined and stored in registers 1002₂ through 1002ₘ, respectively, at the time of manufacture. In such embodiments, the deriving of frequency tuning words FTW2 through FTWm by harmonic distortion measurement circuit 1030 is provided off-chip, for example by way of test equipment. In those embodiments, registers 1000₂ through 1000ₘ may be implemented by non-volatile memory (e.g., electrically-programmable or fuse-programmable memory locations).

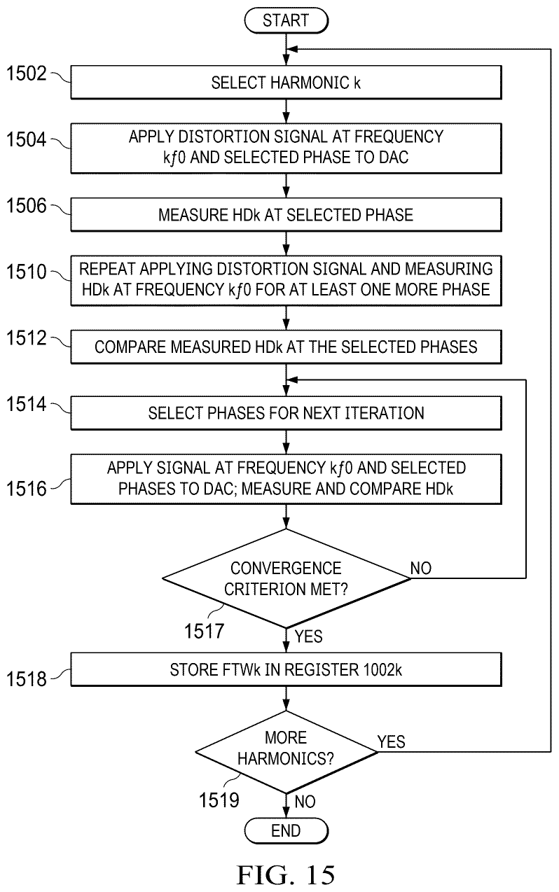

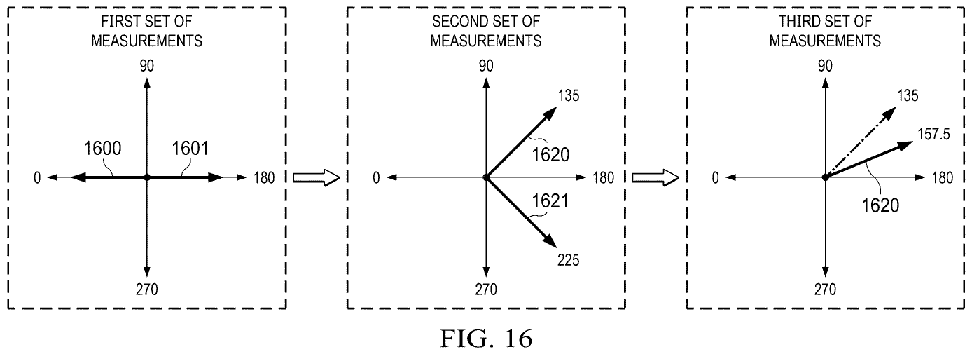

FIG. 15 is a flow diagram of a binary search approach to deriving frequency tuning words FTW2 through FTWm, from which corresponding components of a correction signal applied in DAC 1000 are generated, according to some embodiments. The process of FIG. 15 may be executed by external test equipment, for example, or alternatively by harmonic distortion measurement circuit 1030 within DAC 1000. The operation of the process of FIG. 15 will be described in connection with an example shown in FIG. 16.

In process 1502, a harmonic k is selected, for the determination of its frequency tuning word FTWk. In process 1504, a distortion signal at frequency kf₀ and a selected phase is generated, for example by external test circuitry or by signal generator circuit 1010, and is applied in a sample stream of DAC input codes V[n] to DAC 1000. This distortion signal may be applied in combination with DAC input codes V[n] for a tone at the fundamental frequency f₀. The amplitude of harmonic distortion at frequency kf₀ at the output of DAC 1000 is measured, for example by external test equipment or harmonic distortion measurement circuit 1030, in process 1506. In process 1510, a distortion signal at frequency kf₀ and a different selected phase is applied to DAC 1000, and the harmonic distortion at this different phase is measured. Harmonic distortion at frequency f₀ for at least two phases is thus measured in processes 1506 and 1510. In some embodiments, process 1510 may be repeated one or more additional times. In process 1512, the measured values of harmonic distortion at the selected phases are compared.

In the example of FIG. 16, the left-hand diagram corresponds to the first set of measurements corresponds to processes 1506 and 1510 in the flow diagram of FIG. 15. For example, vector 1600 corresponds to a distortion signal at frequency kf₀ and phase 0° (e.g., as generated and measured in processes 1504, 1506), and vector 1601 corresponds to the distortion signal at phase 180° (e.g., generated and measured in process 1510). Comparison of the measured harmonic distortion at phases 0° and 180° indicates which phase better compensates for the harmonic distortion of DAC 1000 at frequency kf₀ (e.g., results in less measured distortion).

In process 1514 of FIG. 15, one or more phases may be selected for a next iteration of harmonic distortion measurement, based on the results of process 1512. For the example of FIG. 16, a lower distortion measurement at phase 180° relative to that at 0° leads to the selection of phases 135° and 225° in process 1512, as shown in the middle diagram. In process 1516, a distortion signal at the phases selected in process 1514 is applied to DAC 1000, and harmonic distortion at those phases is measured and compared. The comparison in process 1516 may also include the harmonic distortion measurements previously obtained for other phases (e.g., the phases selected in process 1504, or in previous iterations of process 1514). As shown in FIG. 16, vector 1620 represents the distortion signal at a phase of 135°, and vector 1621 represents the distortion signal at a phase of 225°.

Decision 1517 determines whether a convergence criterion for the phase of the compensating distortion signal has been met. An example of the convergence criterion is whether the measured harmonic distortion for one of the phases selected in process 1514 is below a predetermined limit. Alternatively (or in addition), the convergence criterion may be a preselected number of iterations. If the convergence criterion is not met (decision 1517 is “no”), process 1514 is again performed to select one or more additional phases based on the results of the comparison in process 1516.

In the example of FIG. 16, the comparison in process 1516 has determined that the harmonic distortion at a phase of 135° is less than that at a phase of 225°, but more than that at the phase of 180°. Accordingly, one can conclude that the correct compensating phase is between 135° and 180°. In this case, the next iteration of process 1514 can select a single phase, for example at the midpoint of 157.5°, represented by vector 1620 in the right-hand diagram of FIG. 16. Alternatively, two or more phases may be selected in this iteration of process 1514 (e.g., phases 112.5° and 157.5°, if the lowest distortion measurement was at the phase of 135°).

Process 1516 is then performed again at the selected phase or phases (e.g., 157.5° in the example of FIG. 16). Decision 1517 is executed again to determine whether the convergence criterion has been met; if not (decision 1517 is “no”), the process continues with additional phase selection in process 1514.

Upon the convergence criterion being met (decision 1517 is “yes”), evaluation of the phase for harmonic frequency kf₀ is complete. Frequency tuning word FTWk indicating an amplitude and the phase identified in the process of FIG. 15 is stored in register 1002 for harmonic frequency kf₀.

Decision 1519 is then executed to determine if the frequency tuning words remain to be determined at other harmonic frequencies. If so (decision 1519 is “yes”), process 1502 is performed again to select a next harmonic k for analysis, and the process repeats. If all harmonics have been evaluated (decision 1519 is “no”), the process of FIG. 15 is complete.

Example embodiments of the present disclosure are summarized here. Other embodiments can also be understood from the entirety of the specification and the claims filed herein.

Example 1. A digital-to-analog converter circuit including: a thermometric segment corresponding to a number T of input bits, and having first and second output terminals, including: a first plurality of resistors, numbering M, M being at least 2T, each coupled to a first reference voltage terminal, the first plurality of resistors having substantially equal resistances with one another; and a first plurality of switches, numbering at least 2T, each associated with and coupled on one side to a corresponding one of the first plurality of resistors, each of the first plurality of switches configured to couple its associated to the first output terminal or the second output terminal responsive to a control signal for that switch; and an output amplifier having an input coupled to the first output terminal.

Example 2. The circuit of example 1, further including a ground buffer having an output coupled to the second output terminal.

Example 3. The circuit of one of examples 1 or 2, further including: switch logic having an input configured to receive T input bits, and having outputs coupled to the first plurality of switches, the switch logic configured to: receive T input bits representing a first digital value V[n]; responsive to the first digital value V[n], present control signals to the first plurality of switches to cause M×V[n] switches to select the first output terminal and the remaining switches to select the second output terminal; receive T input bits representing a second digital value V[n+1]; and responsive to the second digital value V[n+1], change a selected number C of the control signals to the first plurality of switches to cause M×V[n+1] switches to select the first output terminal and the remaining switches to select the second output terminal, the number C being a constant regardless of whether the second digital value V[n+1] is greater than, less than, or the same as the first digital value V[n].

Example 4. The circuit of one of examples 1 to 3, where the switch logic is configured to change the C control signals to the first plurality of switches, responsive to the second digital value V[n+1], by: encoding a thermometric code responsive to the second digital value V[n+1], the thermometric code expressed as consecutive “1” bits and consecutive “0” bits; comparing the second digital value V[n+1] with the first digital value V[n]; changing a pointer value by an amount determined responsive to whether the second digital value V[n+1] is greater, less than, or the same as the first digital value V[n], and responsive to a random value; shifting the thermometric code responsive to the changed pointer value; and presenting control signals to the first plurality of switches according to the shifted thermometric code.

Example 5. The circuit of one of examples 1 to 4, where the switch logic includes a circular shifter, where the switch logic is further configured to: store the thermometric code in the circular shifter; and shift the stored thermometric code by applying a shift value to the shifter corresponding to the pointer value, and where each of the first plurality of switches is associated with a bit position of the circular shifter.

Example 6. The circuit of one of examples 1 to 5, where the number C is 2, where the switch logic is further configured to randomly select the random value as one of a positive value or a negative value, and where the switch logic is further configured to change the pointer value by: responsive to the second digital value V[n+1] being the same as the first digital value V[n], changing the pointer value by the random value; responsive to the second digital value V[n+1] being greater than the first digital value V[n], changing the pointer value by the difference between the first and second digital values minus the random value; and responsive to the second digital value V[n+1] being less than the first digital value V[n], changing the pointer value by the difference between the first and second digital values plus the random value.

Example 7. The circuit of one of examples 1 to 6, further including: a binary segment corresponding to a number B of input bits, and having an output terminal coupled to the first input of the output amplifier, the binary segment including: a second plurality of resistors, each associated with one of the B input bits and having twice the resistance of a resistor associated with the next most significant bit of the B input bits; and a second plurality of switches, each associated with and coupled on one side to a corresponding one of the second plurality of resistors, each of the second plurality of switches configured to selectively couple its associated resistor to the first output terminal responsive to a control signal for that switch; and switch logic having an input configured to receive a digital value including T input bits and B input bits, the T input bits being more significant in the digital value than the B input bits, and having outputs configured to present control signals to the first plurality of switches and to the second plurality of switches.

Example 8. The circuit of one of examples 1 to 7, further including: an R-2R segment corresponding to a number L of input bits, and having an output terminal coupled to the input of the output amplifier, the R-2R segment including: a third plurality of resistors including first and second resistors for each of the L input bits, where the first resistors for the L input bits are coupled in series between the binary segment and a common potential, and where the second resistor for each of the L input bits is coupled on one side to its associated first resistor; and a third plurality of switches, each associated with one of the L input bits and coupled on one side to the second resistor associated with its input bit, each of the third plurality of switches configured to selectively couple its associated resistor to the first output terminal responsive to a control signal for that switch; and where the input of the switch logic is configured to receive a digital value including T input bits, B input bits, and L input bits, the L input bits being less significant in the digital value than the B input bits, the switch logic further including outputs configured to present control signals to the third plurality of switches.

Example 9. The circuit of one of examples 1 to 8, where the thermometric segment further includes: a second plurality of resistors, numbering at least 2T, each coupled to a second reference voltage terminal, the second plurality of resistors having substantially equal resistances with one another; and a second plurality of switches, numbering at least 2T, each associated with and coupled on one side to a corresponding one of the second plurality of resistors, each of the second plurality of switches configured to select, responsive to a control signal for that switch, the first output terminal or the second output terminal for coupling to its associated resistor, where each of the second plurality of switches is configured to operate in a complementary fashion relative to its associated one of the first plurality of switches; and where the second output terminal is coupled to a second input of the output amplifier.

Example 10. A digital-to-analog converter circuit including: a binary segment having first and second output terminals, the binary segment including one or more slices, each slice corresponding to one of a number B of input bits of an input code, each slice including: a first plurality of resistors, each coupled to a first reference voltage terminal, the first plurality of resistors having substantially equal resistances with one another; a first plurality of switches, each associated with and coupled to a corresponding one of the first plurality of resistors, each of the first plurality of switches configured to select, responsive to a control signal for that switch, the first output terminal or the second output terminal for coupling to its associated resistor; a second plurality of resistors, each coupled to a second reference voltage terminal, the second plurality of resistors having substantially equal resistances with one another and with the first plurality of resistors associated with its bit position; and a second plurality of switches, each associated with and coupled on one side to a corresponding one of the second plurality of resistors, each of the second plurality of switches configured to couple its associated resistor to the first output terminal or the second output terminal, responsive to a control signal for that switch; an output amplifier having an input coupled to the first output terminal; and switch logic, having an input configured to receive B input bits of the input code, and configured to present control signals, to the first and second pluralities of switches of each slice of the binary segment, to couple a single one of the first plurality of resistors to the first output terminal and to couple the other ones of the first plurality of resistors and each of the second plurality of resistors to the second output terminal responsive to the input bit corresponding to the slice having a first logic state, and to couple a single one of the second plurality of resistors to the first output terminal and the other ones of the second plurality of resistors and each of the first plurality of resistors to the second output terminal, responsive to the input bit corresponding to the slice having a second logic state; where each resistor of the first and second pluralities of resistors of each slice has a resistance twice the resistance of resistors of a slice corresponding to a next most significant input bit of the input code.

Example 11. The circuit of example 10, where the switch logic is further configured to: sequentially receive B input bits for a plurality of input codes; where the presenting of control signals to the first and second pluralities of switches of each slice of the binary segment responsive to receiving the second input code value includes changing a state of a number J of the first and second pluralities of switches in each of the slices of the binary segment, the number J being a constant over the plurality of input codes.

Example 12. The circuit of one of examples 10 or 11, where the switch logic is further configured to: for each of the plurality of slices corresponding to an input code bit having the first logic state in a first input code, present control signals to the first plurality of switches to couple a different single one of the first plurality of resistors to the first output terminal responsive to the input code bit of a next successive input code also having the first logic state; and for each of the plurality of slices corresponding to an input code bit having the second logic state in the first input code, present control signals to the second plurality of switches to couple a different single one of the second plurality of resistors to the first output terminal responsive to the input code bit of the next successive input code also having the second logic state.

Example 13. The circuit of one of examples 10 to 12, where the number of resistors in each of the first and second pluralities of resistors of each of the plurality of slices is greater than two.

Example 14. The circuit of one of examples 10 to 13, where the second reference voltage terminal receives a negative voltage of the same magnitude as a voltage received at the first reference voltage terminal.

Example 15. The circuit of one of examples 10 to 14, further including: a thermometric segment having first and second output terminals, the binary segment including a plurality of slices, each slice corresponding to one of a number T of input bits of an input code, each slice including: a third plurality of resistors, numbering at least two, each coupled to the first reference voltage terminal, the third plurality of resistors having substantially equal resistances with one another; and a third plurality of switches, numbering at least two, each associated with and coupled on one side to a corresponding one of the third plurality of resistors, each of the third plurality of switches configured to select, responsive to a control signal for that switch, the first output terminal or the second output terminal for coupling to its associated resistor; a fourth plurality of resistors, numbering at least two, each coupled to the second reference voltage terminal, the fourth plurality of resistors having substantially equal resistances with one another; and a fourth plurality of switches, numbering at least two, each associated with and coupled on one side to a corresponding one of the fourth plurality of resistors, each of the fourth plurality of switches configured to select, responsive to a control signal for that switch, the first output terminal or the second output terminal for coupling to its associated resistor; where the first output terminal of the thermometric segment is coupled to the input of the output amplifier; where the input of the switch logic is further configured to receive T input bits of the input code, the T input bits being more significant bits in the input code than the B input bits; and where the switch logic is further configured to present control signals to the third and fourth pluralities of switches for each of the slices of the thermometric segment responsive to the value represented by the received T input bits of the input code.

Example 16. The circuit of one of examples 10 to 15, further including: an R-2R segment corresponding to a number L of input bits of the input code, including: a fifth plurality of resistors including first and second resistors for each of the L input bits, where the first resistors for the L input bits are coupled in series between the binary segment and a common potential, and where the second resistor for each of the L input bits is coupled on one side to its associated first resistor; and a fifth plurality of switches, each associated with one of the L input bits and coupled on one side to the second resistor associated with its input bit, each of the third plurality of switches configured to selectively couple its associated resistor to the first output terminal responsive to a control signal for that switch; where the first output terminal of the R-2R segment is coupled to the input of the output amplifier; where the input of the switch logic is further configured to receive L input bits of the input code, the L input bits being less significant in the input code than the B input bits; and where the switch logic is further configured to present at least L control signals to the fourth and fifth pluralities of switches responsive to the value represented by the received L input bits of the input code.

Example 17. A digital-to-analog converter circuit including: a thermometric segment having first and second output terminals, and including: a plurality of slices numbering T, where each slice includes a plurality of elements numbering M, each element coupled to a first reference voltage terminal and having substantially equal resistances with one another; an output amplifier having a first input coupled to the first output terminal; and switch logic coupled to the plurality of slices, and configured to: receive T input code bits representing a first digital value VT[n]; responsive to the first digital value VT[n], present control signals to the plurality of slices to couple M×VT[n] elements between the first reference voltage terminal and the first output terminal; receive T input code bits representing a second digital value VT[n+1]; and responsive to the second digital value VT[n+1], change a selected number C of the control signals to couple M×VT[n+1] elements between the first reference voltage terminal and the first output terminal, the number C being a constant regardless of whether the second digital value VT[n+1] is greater than, less than, or the same as the first digital value VT[n].

Example 18. The circuit of example 17, where the thermometric segment has a second output terminal, where each of the plurality of elements in each slice is also coupled to a second reference voltage terminal, and where the switch logic is further configured to present control signals to the plurality of slices to couple, between the second reference voltage terminal and the second output terminal, each element that is not coupled between the first reference voltage terminal and the first output terminal.

Example 19. The circuit of one of examples 17 or 18, where the switch logic is configured to change the C control signals to the plurality of slices, responsive to the second digital value VT[n+1], by: encoding a thermometric code responsive to the second digital value VT[n+1], the thermometric code expressed as consecutive “1” bits and consecutive “0” bits; comparing the second digital value VT[n+1] with the first digital value VT[n]; changing a pointer value by an amount determined responsive to whether the second digital value VT[n+1] is greater, less than, or the same as the first digital value VT[n], and responsive to a random value; shifting the thermometric code responsive to the changed pointer value; and presenting control signals to the plurality of slices according to the shifted thermometric code.

Example 20. The circuit of one of examples 17 to 19, further including: a binary segment having first and second output terminals coupled to the first and second output terminals of the thermometric segment, and including a plurality of binary slices, each binary slice associated with one of B input code bits, the B input code bits less significant than the T input code bits, where each binary slice includes: a first plurality of resistors, each coupled to the first reference voltage terminal, the first plurality of resistors having substantially equal resistances with one another; a first plurality of switches, each associated with and coupled to a corresponding one of the first plurality of resistors, each of the first plurality of switches configured to select, responsive to a control signal for that switch, the first output terminal or the second output terminal for coupling to its associated resistor; a second plurality of resistors, each coupled to the second reference voltage terminal, the second plurality of resistors having substantially equal resistances with one another and with the first plurality of resistors associated with its bit position; and a second plurality of switches, each associated with and coupled on one side to a corresponding one of the second plurality of resistors, each of the second plurality of switches configured to couple its associated resistor to the first output terminal or the second output terminal, responsive to a control signal for that switch; and where the switch logic is further configured to present control signals, to the first and second pluralities of switches of each binary slice of the binary segment responsive to B input code bits, to couple a single one of the first plurality of resistors to the first output terminal and to couple the other ones of the first plurality of resistors and each of the second plurality of resistors to the second output terminal responsive to the input code bit corresponding to the binary slice having a first logic state, and to couple a single one of the second plurality of resistors to the first output terminal and the other ones of the second plurality of resistors and each of the first plurality of resistors to the second output terminal, responsive to the input code bit corresponding to the binary slice having a second logic state; where each resistor of the first and second pluralities of resistors of each binary slice has a resistance twice the resistance of resistors of a slice corresponding to a next most significant input code bit.

Example 21. A digital-to-analog converter system including: a digital-to-analog converter (DAC) having a digital input, having an analog output, and including a number N+E of slices arranged in one or more segments; and a signal generator circuit having an output coupled to the digital input of the DAC, the signal generator circuit configured to generate a digital multitone signal responsive to a first frequency tuning word (FTW) of N bits corresponding to a first tone and a second FTW of N bits corresponding to a second tone, by: at an output pipeline stage, presenting a first code value of the multitone signal to the DAC; and while, in a preceding pipeline stage, performing a calculation of a second code value of the multitone signal.

Example 22. The system of example 21, where the first tone is at a fundamental frequency and the second tone is at a harmonic of the fundamental frequency.

Example 23. The system of one of examples 21 or 22, where the signal generator circuit is configured to perform the calculation of the second code value by: applying the first and second FTWs to first and second phase accumulators, respectively; at a first pipeline stag, sequentially applying remainders from the first and second phase accumulators to a look-up table to obtain first and second sine values, respectively; and at a second pipeline stage, adding the first and second sine values.

Example 24. The system of one of examples 21 to 23, where the signal generator circuit is configured to add the first and second sine values at the second pipeline stage for the second code value of the multitone signal while applying one of the first and second FTWs to the look-up table in the first pipeline stage for a third code value of the multitone signal.

Example 25. The system of one of examples 21 to 24, where the first tone is at a fundamental frequency and the second tone is at a harmonic of the fundamental frequency, the system further including a harmonic distortion measurement circuit having an input coupled to the analog output of the DAC, configured to iteratively compute the second FTW having an amplitude and phase responsive to output analog signals from the DAC.

Example 26. The system of one of examples 21 to 25, where the first tone is at a fundamental frequency and the second tone is at a harmonic of the fundamental frequency, and the signal generator circuit is further configured to generate the digital multitone signal also responsive to a third FTW of N bits corresponding to a third tone at a harmonic of the fundamental frequency.

Example 27. The system of one of examples 21 to 26, where the DAC includes: an R-2R segment corresponding to a number L+E of the least significant N+E slices coupled in series between a first reference voltage terminal and a common potential, each slice including: a first resistor; a second resistor having twice the resistance of the first resistor for its slice, and coupled on one side to the first resistor for its slice; and a switch coupled on one side to the second resistor, and configured to selectively couple its second resistor to the first output terminal responsive to a switch control signal from the signal generator for that slice; and an output amplifier having an input coupled to the first output terminal; where the first resistors for the L+E slices are coupled in series between the first reference voltage terminal and a common potential; and where the signal generator is configured to output digital samples of the multitone signal, each digital sample including switch control signals for each of the L+E slices of the R-2R segment.

Example 28. The system of one of examples 21 to 27, where the DAC further includes: a binary segment having first and second output terminals, the binary segment including a plurality of slices corresponding to a number B of the N+E slices, each slice of the binary segment including: a first plurality of resistors, each coupled to the first reference voltage terminal, the first plurality of resistors having substantially equal resistances with one another; a first plurality of switches, each associated with and coupled to a corresponding one of the first plurality of resistors, each of the first plurality of switches configured to select, responsive to a switch control signal, the first output terminal or the second output terminal for coupling to its associated resistor; a second plurality of resistors, each coupled to a second reference voltage terminal, the second plurality of resistors having substantially equal resistances with one another and with the first plurality of resistors associated with its bit position; and a second plurality of switches, each associated with and coupled on one side to a corresponding one of the second plurality of resistors, each of the second plurality of switches configured to couple its associated resistor to the first output terminal or the second output terminal, responsive to a switch control signal; where each resistor of the first and second pluralities of resistors of each slice has a resistance twice the resistance of resistors of a slice corresponding to a next most significant slice; where the slices of the binary segment correspond to more significant input code bits of the FTWs than the slices of the R-2R segment; where the signal generator is further configured to present switch control signals in each digital sample of the multitone signal to the first and second pluralities of switches of each slice of the binary segment, to couple a single one of the first plurality of resistors to the first output terminal and to couple the other ones of the first plurality of resistors and each of the second plurality of resistors to the second output terminal, responsive to a input code bit of the multitone signal corresponding to the slice having a first logic state, and to couple a single one of the second plurality of resistors to the first output terminal and the other ones of the second plurality of resistors and each of the first plurality of resistors to the second output terminal, responsive to the input code bit of the multitone signal corresponding to the slice having a second logic state; and where the signal generator presents switch control signals to the first and second pluralities of switches of each slice of the binary segment for the second digital sample by changing a number J of the control signals presented to each of the slices of the binary segment from the first digital sample, the number J being a constant over the plurality of slices.

Example 29. The system of one of examples 21 to 28, where the DAC further includes: a thermometric segment including T slices, corresponding to a number T of input code bits, and having first and second output terminals, each slice of the thermometric segment including: a third plurality of resistors, numbering M, M being at least 2T, each coupled to the first reference voltage terminal, the third plurality of resistors having substantially equal resistances with one another; and a third plurality of switches, numbering at least two, each associated with and coupled on one side to a corresponding one of the third plurality of resistors, each of the third plurality of switches configured to select, responsive to a switch control signal, the first output terminal or the second output terminal for coupling to its associated resistor; where the first output terminal of the thermometric segment is coupled to the input of the output amplifier; where the slices of the thermometric segment correspond to more significant input code bits than the slices of the binary segment; where the signal generator is further configured to present switch control signals in each digital sample of the multitone signal to the third and fourth pluralities of switches of each slice of the thermometric segment, by: receiving a value V[n] represented by T bits of the first input code value of the multitone signal; responsive to the value V[n], presenting switch control signals to the first plurality of switches to cause M×V[n] switches to select the first output terminal and the remaining switches to select the second output terminal; receive a value V[n+1] represented by T bits of the second input code value; and responsive to the value V[n+1], change a selected number C of the switch control signals to the first plurality of switches to cause M×V[n+1] switches to select the first output terminal and the remaining switches to select the second output terminal, the number C being a constant regardless of whether the value V[n+1] is greater than, less than, or the same as the value V[n].

Example 30. A digital-to-analog converter circuit including: a signal generator circuit including: a plurality of registers, each for storing an N-bit frequency tuning word (FTW) associated with a tone; a plurality of phase accumulators, each associated with one of the plurality of registers; a multiplexer having inputs coupled to outputs of the plurality of phase accumulators, and having a select input; a first mapping circuit having an input coupled to the output of the multiplexer, and configured to output a sine value; a summing circuit having an input coupled to the output of the first mapping circuit; a buffer having an input coupled to the output of the summing circuit; and pipeline control logic configured to control the multiplexer, the first mapping circuit, the summing circuit, and the buffer, in a pipelined manner; and a DAC array having an input coupled to the output of the buffer, and configured to output an analog signal responsive to a stream of input codes received at its input.

Example 31. The circuit of example 30, where the pipeline control unit is configured to synchronously control the multiplexer, the first mapping circuit, the summing circuit, and the buffer responsive to a clock signal, by: in a first clock cycle, controlling the multiplexer to apply the output of a first phase accumulator associated with a first tone to the first mapping circuit; in a second clock cycle: controlling the multiplexer to apply the output of a second phase accumulator associated with a second tone to the first mapping circuit; and applying a mapped value corresponding to the first tone to the summing circuit; in a third clock cycle: controlling the multiplexer to apply the output of a third phase accumulator associated with a third tone to the first mapping circuit; and applying a mapped value corresponding to the second tone to the summing circuit for addition with the mapped value corresponding to the first tone; and in a fourth clock cycle, storing a first input code value corresponding to the sum of the mapped values for the first, second, and third tones in the buffer.

Example 32. The circuit of one of examples 30 or 31, where the pipeline control unit is configured to control the multiplexer, the first mapping circuit, the summing circuit, and the buffer by, in the fourth clock cycle, controlling the multiplexer to apply the output of one of the phase accumulators to the first mapping circuit to obtain a mapped value for a tone of a second input code.

Example 33. The circuit of one of examples 30 to 32, where the signal generator circuit further includes a second mapping circuit having an input coupled to the output of the first mapping circuit and an output coupled to the input of the summing circuit, where the first mapping circuit maps values at its input according to a triangle waveform, and the second mapping circuit maps values at its input to N+E-bit sine values.

Example 34. The circuit of one of examples 30 to 33, where the signal generator circuit further includes a trim circuit having an input coupled to the output of the summing circuit and an output coupled to an input of the buffer, the trim circuit configured to apply a static correction.

Example 35. The circuit of one of examples 30 to 34, where the DAC includes a number N+E of slices arranged in one or more segments: an R-2R segment corresponding to a number L+E of the least significant N+E slices coupled in series between a first reference voltage terminal and a common potential, each slice including: a first resistor; a second resistor having twice the resistance of the first resistor for its slice, and coupled on one side to the first resistor for its slice; and a switch coupled on one side to the second resistor, and configured to selectively couple its second resistor to the first output terminal responsive to a switch control signal from the signal generator for that slice; and an output amplifier having an input coupled to the first output terminal; where the first resistors for the L+E slices are coupled in series between the first reference voltage terminal and a common potential; and where the signal generator circuit outputs input code values including switch control signals for each of the L+E slices of the R-2R segment.

Example 36. A digital-to-analog converter system including: a digital-to-analog converter (DAC) having a digital input, having an analog output, and including a number N+E of slices arranged in one or more segments; a signal generator circuit having an output coupled to the digital input of the DAC, the signal generator circuit configured to generate a digital multitone signal responsive to a first frequency tuning word (FTW) of N bits corresponding to a a fundamental frequency and a second FTW of N bits corresponding to a harmonic frequency of the fundamental frequency, by: at an output pipeline stage, presenting a first code value of the multitone signal to the DAC; and while, in a preceding pipeline stage, performing a calculation of a second code value of the multitone signal; and a harmonic distortion measurement circuit having an input coupled to the analog output of the DAC, configured to iteratively compute the second FTW having an amplitude and phase responsive to output analog signals from the DAC.

Example 37. The system of example 36, where the harmonic distortion measurement circuit is configured to iteratively compute the second FTW by: applying, to the DAC, a distortion signal at the harmonic frequency, at first and second phases; measuring and comparing distortion at the analog output of the DAC responsive to the distortion signal at the harmonic frequency for each of the first and second phases; responsive to the comparing of distortion at the first and second phases, applying, to the DAC, a distortion signal at the harmonic frequency, and at one or more additional phases; measuring distortion at the harmonic frequency for the one or more additional phases; determining, responsive to the measured distortion at the harmonic frequency for the one or more additional phases, whether a convergence criterion is met; responsive to the convergence criterion not being met, repeating the applying of a distortion signal to the DAC at the harmonic frequency and at one or more phases, the measuring distortion, and the determining whether the convergence criterion is met; and responsive to the convergence criterion being met, storing the second FTW for the harmonic frequency in a register.

Example 38. The system of one of examples 36 or 37, where the signal generator circuit is configured to perform the calculation of the second code value by: applying the first and second FTWs to first and second phase accumulators, respectively; at a first pipeline stage, sequentially applying remainders from the first and second phase accumulators to a look-up table to obtain first and second sine values, respectively; and at a second pipeline stage, adding the first and second sine values; and where the signal generator circuit is configured to add the first and second sine values at the second pipeline stage for the second code value of the multitone signal while applying one of the first and second FTWs to the look-up table in the first pipeline stage for a third code value of the multitone signal.

Example 39. The system of one of examples 36 to 38, where the harmonic distortion measurement circuit iteratively computes the second FTW at manufacture of an integrated circuit including the DAC.

Example 40. The system of one of examples 36 to 39, where the DAC includes a plurality of slices arranged in one or more segments, including an R-2R segment corresponding to a plurality of R-2R slices coupled in series between a first reference voltage terminal and a common potential, each R-2R slice including: a first resistor; a second resistor, having twice the resistance of the first resistor for its slice, and coupled on one side to the first resistor for its R-2R slice; and a switch coupled on one side to the second resistor, and configured to selectively couple its second resistor to the first output terminal responsive to a switch control signal from the signal generator for that R-2R slice; and an output amplifier, having an input coupled to the first output terminal; where the first resistors for the R-2R slices are coupled in series between the first reference voltage terminal and a common potential; and where the signal generator circuit outputs input code values including switch control signals for each of the R-2R slices. Examples are described in this specification as implemented into digital to analog conversion circuits and systems, as such implementation can be advantageous in that context. However, aspects of these examples may be beneficially applied in alternative applications, for example larger-scale integrated systems including one or more DAC functions. Accordingly, the above description is provided by way of example only, and is not intended to limit the true scope as claimed.

Unless otherwise stated, “about,” “approximately,” or “substantially” preceding a value means+/−10 percent of the stated value. Modifications are possible in the described examples, and other examples are possible within the scope of the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. While, in some example embodiments, certain elements are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Circuits described herein may be reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Modifications are possible in the described embodiments, and other embodiments are possible, within the scope of the claims.

What is claimed is:

1. A digital-to-analog converter circuit, comprising:
a thermometric segment corresponding to a number T of input bits, and having first and second output terminals, comprising:
a first plurality of resistors, numbering M, M being at least 2T, each coupled to a first reference voltage terminal, the first plurality of resistors having substantially equal resistances with one another; and
a first plurality of switches, numbering at least 2T, each associated with and coupled on one side to a corresponding one of the first plurality of resistors, each of the first plurality of switches configured to couple its associated to the first output terminal or the second output terminal responsive to a control signal for that switch; and
an output amplifier having an input coupled to the first output terminal.

2. The circuit of claim 1, further comprising:
a ground buffer, having an output coupled to the second output terminal.

3. The circuit of claim 1, further comprising:
switch logic, having an input configured to receive T input bits, and having outputs coupled to the first plurality of switches, the switch logic configured to:
receive T input bits representing a first digital value V[n];
responsive to the first digital value V[n], present control signals to the first plurality of switches to cause M×V[n] switches to select the first output terminal and the remaining switches to select the second output terminal;
receive T input bits representing a second digital value V[n+1]; and
responsive to the second digital value V[n+1], change a selected number C of the control signals to the first plurality of switches to cause M×V[n+1] switches to select the first output terminal and the remaining switches to select the second output terminal, the number C being a constant regardless of whether the second digital value V[n+1] is greater than, less than, or the same as the first digital value V[n].

4. The circuit of claim 3, wherein the switch logic is configured to change the C control signals to the first plurality of switches, responsive to the second digital value V[n+1], by:
encoding a thermometric code responsive to the second digital value V[n+1], the thermometric code expressed as consecutive “1” bits and consecutive “0” bits;
comparing the second digital value V[n+1] with the first digital value V[n];
changing a pointer value by an amount determined responsive to whether the second digital value V[n+1] is greater, less than, or the same as the first digital value V[n], and responsive to a random value;
shifting the thermometric code responsive to the changed pointer value; and
presenting control signals to the first plurality of switches according to the shifted thermometric code.

5. The circuit of claim 4, wherein the switch logic comprises a circular shifter:
wherein the switch logic is further configured to:
store the thermometric code in the circular shifter; and
shift the stored thermometric code by applying a shift value to the shifter corresponding to the pointer value, and wherein each of the first plurality of switches is associated with a bit position of the circular shifter.

6. The circuit of claim 4, wherein the number Cis 2, wherein the switch logic is further configured to randomly select the random value as one of a positive value or a negative value, and wherein the switch logic is further configured to change the pointer value by:
responsive to the second digital value V[n+1] being the same as the first digital value V[n], changing the pointer value by the random value;
responsive to the second digital value V[n+1] being greater than the first digital value V[n], changing the pointer value by the difference between the first and second digital values minus the random value; and
responsive to the second digital value V[n+1] being less than the first digital value V[n], changing the pointer value by the difference between the first and second digital values plus the random value.

7. The circuit of claim 1, further comprising:
a binary segment corresponding to a number B of input bits, and having an output terminal coupled to the first input of the output amplifier, the binary segment comprising:
a second plurality of resistors, each associated with one of the B input bits and having twice the resistance of a resistor associated with the next most significant bit of the B input bits; and
a second plurality of switches, each associated with and coupled on one side to a corresponding one of the second plurality of resistors, each of the second plurality of switches configured to selectively couple its associated resistor to the first output terminal responsive to a control signal for that switch; and
switch logic, having an input configured to receive a digital value including T input bits and B input bits, the T input bits being more significant in the digital value than the B input bits, and having outputs configured to present control signals to the first plurality of switches and to the second plurality of switches.

8. The circuit of claim 7, further comprising:
an R-2R segment corresponding to a number L of input bits, and having an output terminal coupled to the input of the output amplifier, the R-2R segment comprising:
a third plurality of resistors including first and second resistors for each of the L input bits, wherein the first resistors for the L input bits are coupled in series between the binary segment and a common potential, and wherein the second resistor for each of the L input bits is coupled on one side to its associated first resistor; and
a third plurality of switches, each associated with one of the L input bits and coupled on one side to the second resistor associated with its input bit, each of the third plurality of switches configured to selectively couple its associated resistor to the first output terminal responsive to a control signal for that switch;
and wherein the input of the switch logic is configured to receive a digital value including T input bits, B input bits, and L input bits, the L input bits being less significant in the digital value than the B input bits, the switch logic further including outputs configured to present control signals to the third plurality of switches.

9. The circuit of claim 3, wherein the thermometric segment further comprises:
a second plurality of resistors, numbering at least 2T, each coupled to a second reference voltage terminal, the second plurality of resistors having substantially equal resistances with one another; and
a second plurality of switches, numbering at least 2T, each associated with and coupled on one side to a corresponding one of the second plurality of resistors, each of the second plurality of switches configured to select, responsive to a control signal for that switch, the first output terminal or the second output terminal for coupling to its associated resistor, wherein each of the second plurality of switches is configured to operate in a complementary fashion relative to its associated one of the first plurality of switches;
and wherein the second output terminal is coupled to a second input of the output amplifier.

10. A digital-to-analog converter circuit, comprising:
a binary segment having first and second output terminals, the binary segment comprising one or more slices, each slice corresponding to one of a number B of input bits of an input code, each slice comprising:
a first plurality of resistors, each coupled to a first reference voltage terminal, the first plurality of resistors having substantially equal resistances with one another;
a first plurality of switches, each associated with and coupled to a corresponding one of the first plurality of resistors, each of the first plurality of switches configured to select, responsive to a control signal for that switch, the first output terminal or the second output terminal for coupling to its associated resistor;
a second plurality of resistors, each coupled to a second reference voltage terminal, the second plurality of resistors having substantially equal resistances with one another and with the first plurality of resistors associated with its bit position; and
a second plurality of switches, each associated with and coupled on one side to a corresponding one of the second plurality of resistors, each of the second plurality of switches configured to couple its associated resistor to the first output terminal or the second output terminal, responsive to a control signal for that switch;
an output amplifier having an input coupled to the first output terminal; and
switch logic, having an input configured to receive B input bits of the input code, and configured to present control signals, to the first and second pluralities of switches of each slice of the binary segment, to couple a single one of the first plurality of resistors to the first output terminal and to couple the other ones of the first plurality of resistors and each of the second plurality of resistors to the second output terminal responsive to the input bit corresponding to the slice having a first logic state, and to couple a single one of the second plurality of resistors to the first output terminal and the other ones of the second plurality of resistors and each of the first plurality of resistors to the second output terminal, responsive to the input bit corresponding to the slice having a second logic state;
wherein each resistor of the first and second pluralities of resistors of each slice has a resistance twice the resistance of resistors of a slice corresponding to a next most significant input bit of the input code.

11. The circuit of claim 10, wherein the switch logic is further configured to:
sequentially receive B input bits for a plurality of input codes;
wherein the presenting of control signals to the first and second pluralities of switches of each slice of the binary segment responsive to receiving the second input code value comprises changing a state of a number J of the first and second pluralities of switches in each of the slices of the binary segment, the number J being a constant over the plurality of input codes.

12. The circuit of claim 11, wherein the switch logic is further configured to:
for each of the plurality of slices corresponding to an input code bit having the first logic state in a first input code, present control signals to the first plurality of switches to couple a different single one of the first plurality of resistors to the first output terminal responsive to the input code bit of a next successive input code also having the first logic state; and
for each of the plurality of slices corresponding to an input code bit having the second logic state in the first input code, present control signals to the second plurality of switches to couple a different single one of the second plurality of resistors to the first output terminal responsive to the input code bit of the next successive input code also having the second logic state.

13. The circuit of claim 12, wherein the number of resistors in each of the first and second pluralities of resistors of each of the plurality of slices is greater than two.

14. The circuit of claim 10, wherein the second reference voltage terminal receives a negative voltage of the same magnitude as a voltage received at the first reference voltage terminal.

15. The circuit of claim 10, further comprising:
a thermometric segment, having first and second output terminals, the binary segment comprising a plurality of slices, each slice corresponding to one of a number T of input bits of an input code, each slice comprising:
a third plurality of resistors, numbering at least two, each coupled to the first reference voltage terminal, the third plurality of resistors having substantially equal resistances with one another; and
a third plurality of switches, numbering at least two, each associated with and coupled on one side to a corresponding one of the third plurality of resistors, each of the third plurality of switches configured to select, responsive to a control signal for that switch, the first output terminal or the second output terminal for coupling to its associated resistor;
a fourth plurality of resistors, numbering at least two, each coupled to the second reference voltage terminal, the fourth plurality of resistors having substantially equal resistances with one another; and
a fourth plurality of switches, numbering at least two, each associated with and coupled on one side to a corresponding one of the fourth plurality of resistors, each of the fourth plurality of switches configured to select, responsive to a control signal for that switch, the first output terminal or the second output terminal for coupling to its associated resistor;
wherein the first output terminal of the thermometric segment is coupled to the input of the output amplifier;
wherein the input of the switch logic is further configured to receive T input bits of the input code, the T input bits being more significant bits in the input code than the B input bits;
and wherein the switch logic is further configured to present control signals to the third and fourth pluralities of switches for each of the slices of the thermometric segment responsive to the value represented by the received T input bits of the input code.

16. The circuit of claim 15, further comprising:
an R-2R segment corresponding to a number L of input bits of the input code, comprising:
a fifth plurality of resistors including first and second resistors for each of the L input bits, wherein the first resistors for the L input bits are coupled in series between the binary segment and a common potential, and wherein the second resistor for each of the L input bits is coupled on one side to its associated first resistor; and
a fifth plurality of switches, each associated with one of the L input bits and coupled on one side to the second resistor associated with its input bit, each of the third plurality of switches configured to selectively couple its associated resistor to the first output terminal responsive to a control signal for that switch;
wherein the first output terminal of the R-2R segment is coupled to the input of the output amplifier;
wherein the input of the switch logic is further configured to receive L input bits of the input code, the L input bits being less significant in the input code than the B input bits;
and wherein the switch logic is further configured to present at least L control signals to the fourth and fifth pluralities of switches responsive to the value represented by the received L input bits of the input code.

17. A digital-to-analog converter circuit, comprising:
a thermometric segment having first and second output terminals, and comprising:
a plurality of slices numbering T, wherein each slice comprises a plurality of elements numbering M, each element coupled to a first reference voltage terminal and having substantially equal resistances with one another;
an output amplifier having a first input coupled to the first output terminal; and
switch logic, coupled to the plurality of slices, and configured to:
receive T input code bits representing a first digital value V_{T}[n];
responsive to the first digital value V_{T}[n], present control signals to the plurality of slices to couple M×V_{T}[n] elements between the first reference voltage terminal and the first output terminal;
receive T input code bits representing a second digital value V_{T}[n+1]; and
responsive to the second digital value V_{T}[n+1], change a selected number C of the control signals to couple M×V_{T}[n+1] elements between the first reference voltage terminal and the first output terminal, the number C being a constant regardless of whether the second digital value V_{T}[n+1] is greater than, less than, or the same as the first digital value V_{T}[n].

18. The circuit of claim 17, wherein the thermometric segment has a second output terminal;
wherein each of the plurality of elements in each slice is also coupled to a second reference voltage terminal;
and wherein the switch logic is further configured to:
present control signals to the plurality of slices to couple, between the second reference voltage terminal and the second output terminal, each element that is not coupled between the first reference voltage terminal and the first output terminal.

19. The circuit of claim 18, wherein the switch logic is configured to change the C control signals to the plurality of slices, responsive to the second digital value V_{T}[n+1], by:
encoding a thermometric code responsive to the second digital value V_{T}[n+1], the thermometric code expressed as consecutive “1” bits and consecutive “0” bits;
comparing the second digital value V_{T}[n+1] with the first digital value V_{T}[n];
changing a pointer value by an amount determined responsive to whether the second digital value V_{T}[n+1] is greater, less than, or the same as the first digital value V_{T}[n], and responsive to a random value;
shifting the thermometric code responsive to the changed pointer value; and
presenting control signals to the plurality of slices according to the shifted thermometric code.

20. The circuit of claim 17, further comprising:
a binary segment having first and second output terminals coupled to the first and second output terminals of the thermometric segment, and comprising a plurality of binary slices, each binary slice associated with one of B input code bits, the B input code bits less significant than the T input code bits, wherein each binary slice comprises:
a first plurality of resistors, each coupled to the first reference voltage terminal, the first plurality of resistors having substantially equal resistances with one another;
a first plurality of switches, each associated with and coupled to a corresponding one of the first plurality of resistors, each of the first plurality of switches configured to select, responsive to a control signal for that switch, the first output terminal or the second output terminal for coupling to its associated resistor;
a second plurality of resistors, each coupled to the second reference voltage terminal, the second plurality of resistors having substantially equal resistances with one another and with the first plurality of resistors associated with its bit position; and
a second plurality of switches, each associated with and coupled on one side to a corresponding one of the second plurality of resistors, each of the second plurality of switches configured to couple its associated resistor to the first output terminal or the second output terminal, responsive to a control signal for that switch;
and wherein the switch logic is further configured to present control signals, to the first and second pluralities of switches of each binary slice of the binary segment responsive to B input code bits, to couple a single one of the first plurality of resistors to the first output terminal and to couple the other ones of the first plurality of resistors and each of the second plurality of resistors to the second output terminal responsive to the input code bit corresponding to the binary slice having a first logic state, and to couple a single one of the second plurality of resistors to the first output terminal and the other ones of the second plurality of resistors and each of the first plurality of resistors to the second output terminal, responsive to the input code bit corresponding to the binary slice having a second logic state;
wherein each resistor of the first and second pluralities of resistors of each binary slice has a resistance twice the resistance of resistors of a slice corresponding to a next most significant input code bit.
